(19) United States
(12) Patent Application Publication
(10) Pub. No.: US 2025/0293126 A1
(43) Pub. Date: Sep. 18, 2025

(54) ELECTRONIC DEVICE

(71) Applicant: Rohm Co., Ltd., Kyoto-shi (JP)

(72) Inventors: Takahiro NEGORO, Kyoto-shi (JP); Ryohei UMENO, Kyoto-shi (JP)

(21) Appl. No.: 19/076,442

(22) Filed: Mar. 11, 2025

(30) Foreign Application Priority Data
Mar. 15, 2024 (JP) 2024-041049

(51) Int. Cl. H01L 23/495; H01L 21/48; H01L 23/00; H01L 23/31; H01L 25/07

(52) U.S. Cl. CPC H01L 23/49544; H01L 23/49575; H01L 25/072; H01L 21/4842; H01L 23/3107; H01L 24/48; H01L 2224/48137; H01L 2224/48247

(57) ABSTRACT

An electronic device including a first electronic component, a sealing resin, and a first lead including an inner portion and an outer portion. The inner portion includes a die pad on which the first electronic component is mounted, and a connecting portion connecting the outer portion and the die pad. The outer portion is located on one side in a first direction, with respect to the die pad. The center of the outer portion is located on one side of the center of the die pad, in a second direction. As viewed in a thickness direction, the distance from a first end of a first cutting mark of the outer portion, in the first direction, to a first corner portion of the die pad, is 10.8 times or less, of a first length of the outer portion in the second direction.

### TECHNICAL FIELD

The present disclosure relates to an electronic device.

### BACKGROUND ART

Various electronic devices thus far known include a semiconductor device, manufactured with a lead frame. An example of such a semiconductor device is disclosed in JP-A-2022-55599.

The semiconductor device according to this document is configured to be mounted on a circuit board of an inverter, and includes a first semiconductor element, a conductive support member, and a sealing resin. The conductive support member is formed of a single lead frame. The conductive support member includes a first die pad and a plurality of input-side terminals. On the first die pad, the first semiconductor element is mounted. Some of the plurality of input-side terminals are connected to the first die pad.

Like the semiconductor device according to JP-A-2022-55599, the existing electronic devices include those in which the electronic component is mounted on the lead frame. In the case of such an electronic device, for example, it is required to suppress deformation of the lead frame, to improve the reliability. In the case where the lead frame is deformed, such that the position of the die pad, in other words the position where the electronic component is to be mounted, is shifted, the electronic component may fail to be properly mounted on the die pad.

### BRIEF DESCRIPTION OF THE DRAWINGS

FIG. 1 is a plan view showing an electronic device according to a first embodiment of the present disclosure;

FIG. 2 is a plan view corresponding to FIG. 1, in which a sealing resin is indicated by imaginary lines;

FIG. 3 is a partially enlarged plan view of a portion in FIG. 2;

FIG. 4 is a partially enlarged plan view of another portion in FIG. 2;

FIG. 5 is a front view showing the electronic device according to the first embodiment of the present disclosure;

FIG. 6 is a rear view showing the electronic device according to the first embodiment of the present disclosure;

FIG. 7 is a left-side view showing the electronic device according to the first embodiment of the present disclosure;

FIG. 8 is a right-side view showing the electronic device according to the first embodiment of the present disclosure;

FIG. 9 is a cross-sectional view taken along a line IX-IX in FIG. 2;

FIG. 10 is a cross-sectional view taken along a line X-X in FIG. 2;

FIG. 11 is a circuit diagram of the electronic device according to the first embodiment of the present disclosure;

FIG. 12 is a plan view for explaining a manufacturing process of the electronic device according to the first embodiment of the present disclosure;

FIG. 13 is a plan view showing an electronic device according to a second embodiment of the present disclosure, in which the sealing resin is indicated by imaginary lines;

FIG. 14 is a partially enlarged plan view of a portion in FIG. 13;

FIG. 15 is a partially enlarged plan view of another portion in FIG. 13;

FIG. 16 is a front view showing the electronic device according to the second embodiment of the present disclosure;

FIG. 17 is a rear view showing the electronic device according to the second embodiment of the present disclosure;

FIG. 18 is a plan view showing an electronic device according to a variation of the second embodiment, in which the sealing resin is indicated by imaginary lines;

FIG. 19 is a partially enlarged plan view of a portion in FIG. 18;

FIG. 20 is a partially enlarged plan view of another portion in FIG. 18;

FIG. 21 is a front view showing the electronic device according to the variation of the second embodiment;

FIG. 22 is a rear view showing the electronic device according to the variation of the second embodiment;

FIG. 23 is a plan view showing an electronic device according to a third embodiment of the present disclosure, in which the sealing resin is indicated by imaginary lines;

FIG. 24 is a partially enlarged plan view of a portion in FIG. 23;

FIG. 25 is a partially enlarged plan view of another portion in FIG. 23;

FIG. 26 is a front view showing the electronic device according to the third embodiment of the present disclosure; and

FIG. 27 is a rear view showing the electronic device according to the third embodiment of the present disclosure.

### DETAILED DESCRIPTION OF EMBODIMENTS

Hereafter, exemplary embodiments of the present disclosure will be described in detail, with reference to the drawings.

The terms “first”, “second”, “third”, and so forth used in the present disclosure merely serve as a label, and are not necessarily intended to specify an order with respect to the objects accompanied with these terms.

In the description of the present disclosure, the expression “an object A is formed in an object B”, and “an object A is formed on an object B” imply the situation where, unless otherwise specifically noted, “the object A is formed directly in or on the object B”, and “the object A is formed in or on the object B, with something else interposed between the object A and the object B”. Likewise, the expression “an object A is arranged in an object B”, and “an object A is arranged on an object B” imply the situation where, unless otherwise specifically noted, “the object A is arranged directly in or on the object B”, and “the object A is arranged in or on the object B, with something else interposed between the object A and the object B”. Further, the expression “an object A is located on an object B” implies the situation where, unless otherwise specifically noted, “the object A is located on the object B, in contact with the object B”, and “the object A is located on the object B, with something else interposed between the object A and the object B”. The expression “an object A is overlapping with an object B as viewed in a certain direction” implies the situation where, unless otherwise specifically noted, “the object A is overlapping with the entirety of the object B”, and “the object A is overlapping with a part of the object B”. Further, the expression “(The material of) an object A includes a material C” implies the situation where “(The material of) the object A is constituted of the material C”, and “A predominant component of (the material of) the object A is the material C”. Still further, in the present disclosure, the expression “A face A is oriented (to one side or the other side) in a direction B” is not limited to the situation where the face A is orthogonal (90°) to the direction B, but includes the case where the face A is inclined with respect to the direction B.

### First Embodiment

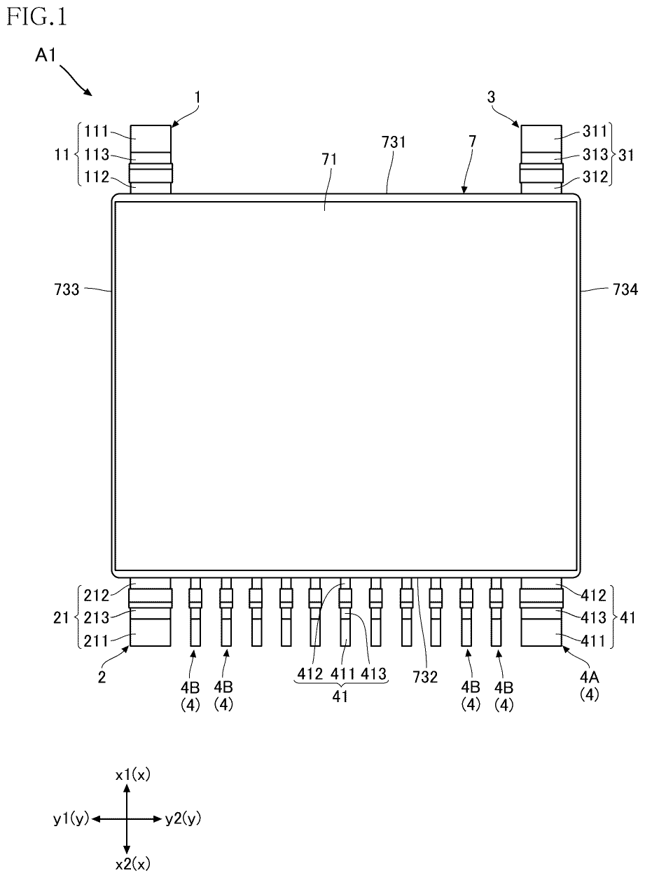

FIG. 1 to FIG. 13 each illustrate an electronic device according to a first embodiment of the present disclosure. The electronic device A1 according to this embodiment includes a first lead 1, a second lead 2, a third lead 3, a plurality of fourth leads 4, a first electronic component 51, a second electronic component 52, a plurality of connection members 61 to 66, and a sealing resin 7. Although the electronic device A1 includes twelve fourth leads 4 in the illustrated example, the number of fourth leads 4 is not specifically limited. Although the purpose of use of the electronic device A1 is not specifically limited, the electronic device A1 may be used, for example, to detect a battery voltage of an electric vehicle. The electronic device A1 may also detect, instead of the battery voltage of the electric vehicle, the voltage of another parts, or a voltage in an industrial apparatus, home electric appliances, or a power source device, without limitation to the electric vehicle. The electronic device A1 is a semiconductor package of a surface-mounting type and, as shown in FIG. 1 and FIG. 5 to FIG. 8, of a small outline package (SOP) type in this embodiment.

For the sake of convenience in description, a thickness direction z, a first direction x, and a second direction y, which are orthogonal to each other, will be referred to. The thickness direction z corresponds to the thickness direction of the electronic device A1 (first electronic component 51). The term “plan view” refers to a view in the thickness direction z. The first direction x is orthogonal to the thickness direction z. The second direction y is orthogonal to the thickness direction z and the first direction x. In addition, one side of the first direction x will be referred to as x1-side of the first direction x, and the other side of the first direction x will be referred to as x2-side of the first direction x. Likewise, one side of the second direction y will be referred to as y1-side of the second direction y, and the other side of the second direction y will be referred to as y2-side of the second direction y. One side of the thickness direction z will be referred to as z1-side of the thickness direction z, and the other side of the thickness direction z will be referred to as z2-side of the thickness direction z. In this relation, the z2-side of the thickness direction z may be referred to as upper side, and the z1-side of the thickness direction z may be referred to as lower side. Further, the expressions “upper”, “lower”, “upward”, “downward”, “upper face”, “lower face”, and so forth indicate relative positional relations between the components with respect to the z-direction, and are not necessarily intended to define the relation with the gravity direction.

The first lead 1, the second lead 2, the third lead 3, and the plurality of fourth leads 4 include a metal, such as copper (Cu), nickel (Ni), and iron (Fe). The first lead 1, the second lead 2, the third lead 3, and the plurality of fourth leads 4 are formed of the same lead frame (lead frame 9 to be subsequently described). Examples of the metal material for constituting the lead frame 9 include a Cu-tin (Sn) alloy, and a Fe-Ni alloy such as 42-alloy. The first lead 1, the second lead 2, the third lead 3, and the plurality of fourth leads 4 may be formed by performing a processing selected from punching, bending, and etching, on a metal plate material. Further, a plated layer of silver (Ag), Ni, or gold (Au) may be formed, as necessary, on a predetermined position on each of the first lead 1, the second lead 2, the third lead 3, and the plurality of fourth leads 4.

The first lead 1, the second lead 2, the third lead 3, and the plurality of fourth leads 4 are electrically continuous with the first electronic component 51 or the second electronic component 52, and constitutes a conduction path in the electronic device A1. The first lead 1, the second lead 2, the third lead 3, and the plurality of fourth leads 4 are spaced apart from each other. The first lead 1, the second lead 2, the third lead 3, and the plurality of fourth leads 4 each include a portion covered with the sealing resin 7, and a portion exposed from the sealing resin 7.

The first lead 1 includes a first outer portion 11 and a first inner portion 12. The first outer portion 11 and the first inner portion 12 are integrally formed, so as to be continuous with each other. The boundary between the first outer portion 11 and the first inner portion 12 overlaps with the peripheral edge of the scaling resin 7, in a plan view.

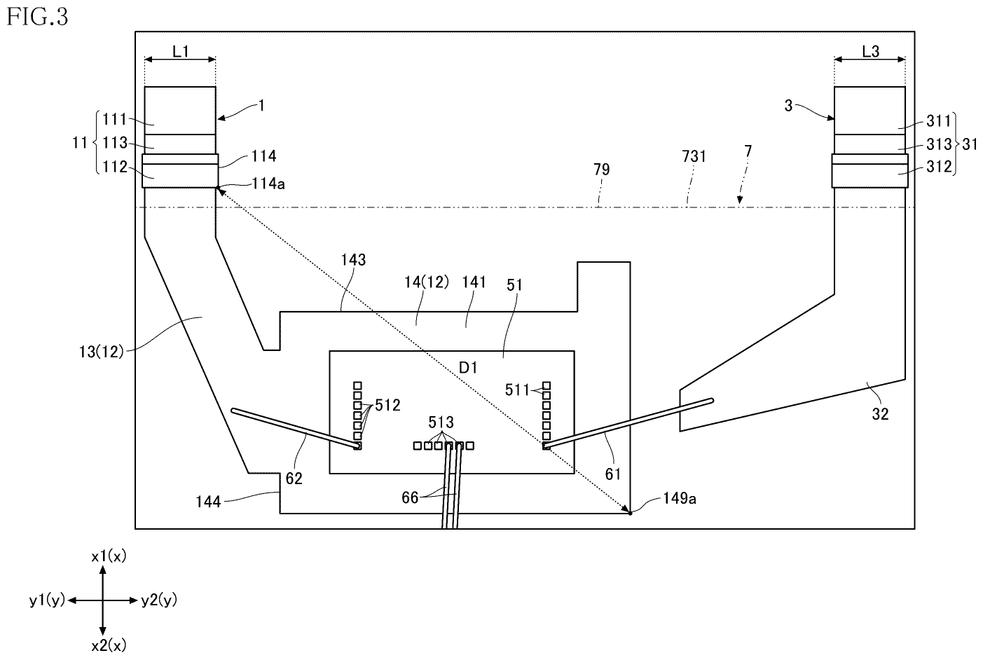

The first outer portion 11 corresponds to the portion of the first lead 1 exposed from the scaling resin 7. The first outer portion 11 is protruding from the sealing resin 7, to the x1-side of the first direction x. The first outer portion 11 has a rectangular shape, having the longer sides extending in the first direction x, in a plan view. The first outer portion 11 is bent in a gullwing shape, as viewed in the second direction y. A first length L1 (see FIG. 3) of the first outer portion 11 in the second direction y is not specifically limited, but may be, for example, between 0.1 mm and 1.5 mm, both ends inclusive. The first outer portion 11 includes a first mounting portion 111, a first basal portion 112, and a first intermediate portion 113.

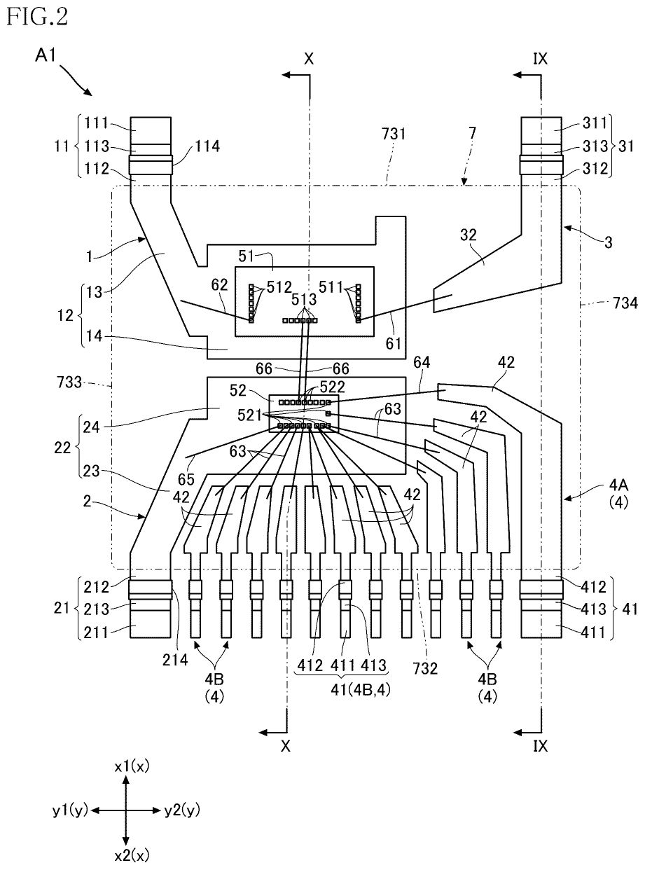

The first mounting portion 111 corresponds to the distal end portion of the first outer portion 11. When the electronic device A1 is mounted on a circuit board, the first mounting portion 111 is joined to the circuit board. As shown in FIG. 1 and FIG. 2, the first mounting portion 111 is located on the end portion on the opposite side of the sealing resin 7, in the first direction x. Accordingly, the first mounting portion 111 is located more distant from the sealing resin 7 in the first direction x, than the first basal portion 112 and the first intermediate portion 113. The first mounting portion 111 is located on the lower side in the thickness direction z, with respect to the first basal portion 112.

The first basal portion 112 corresponds to the basal portion of the first outer portion 11. As shown in FIG. 1 and FIG. 2, the first basal portion 112 is located at the end portion of the first outer portion 11 closest to the sealing resin 7, in the first direction x. In other words, the first basal portion 112 is located closer to the sealing resin 7 in the first direction x, than are the first mounting portion 111 and the first intermediate portion 113. The first basal portion 112 is located on the upper side of the first mounting portion 111 in the thickness direction z, and protruding from the central portion of the sealing resin 7 in the thickness direction z.

The first intermediate portion 113 is continuous with the first mounting portion 111 and the first basal portion 112. The first intermediate portion 113 is inclined with respect to the first mounting portion 111 and the first basal portion 112, as viewed in the second direction y. In this embodiment, the first intermediate portion 113 is inclined with respect to the thickness direction z.

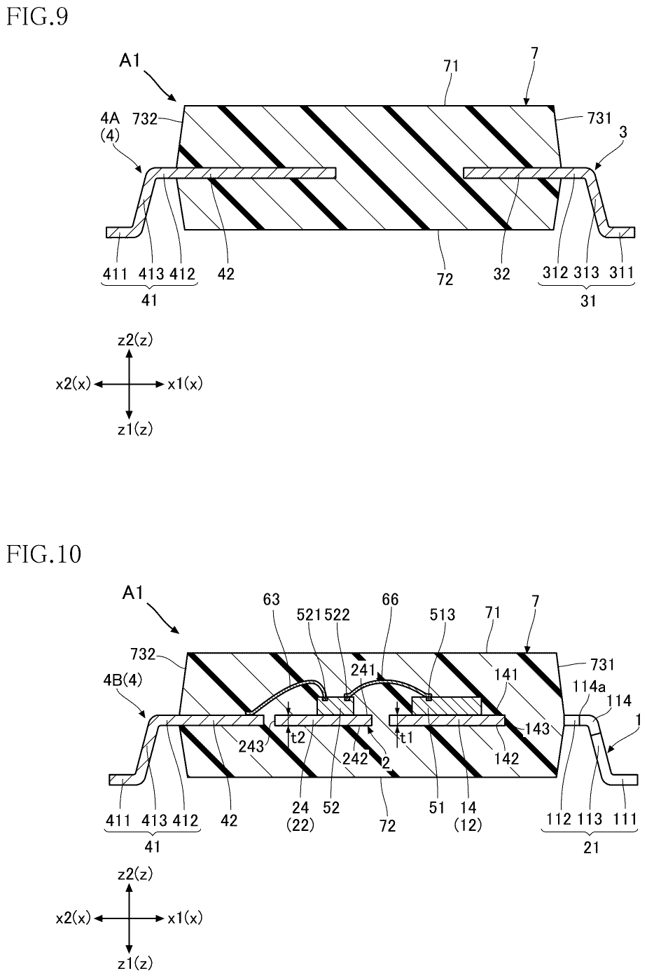

In this embodiment, the first outer portion 11 includes a first cutting mark 114. The first cutting mark 114 is formed, when the first outer portion 11 is formed from the lead frame 9 to be subsequently described, by cutting a part of the lead frame 9. The first cutting mark 114 is oriented to the y2-side of the second direction y, and formed so as to stride over the first basal portion 112 and the first intermediate portion 113 (see FIG. 10). The first cutting mark 114 is higher in surface roughness, than the remaining portions of the first outer portion 11. In addition, the first cutting mark 114 is slightly protruding toward the y2-side of the second direction y, with respect to the remaining faces of the first outer portion 11 oriented to the y2-side of the second direction y. In the drawings, the extent of protrusion of the first cutting mark 114, to the y2-side of the second direction y, is exaggerated.

The first inner portion 12 corresponds to the portion of the first lead 1 covered with the scaling resin 7. The first inner portion 12 extends from the first outer portion 11 toward the inner region of the sealing resin 7. The first inner portion 12 includes a first connecting portion 13 and a first die pad 14.

The first connecting portion 13 extends from the first outer portion 11 toward the inner region of the scaling resin 7. The first connecting portion 13 is continuous with the first die pad 14. In other words, the first connecting portion 13 is connecting the first inner portion 12 and the first die pad 14.

The first die pad 14 supports the first electronic component 51, when the first electronic component 51 is mounted thereon. The first connecting portion 13 is connected to the first die pad 14, and the first die pad 14 is supported by the first connecting portion 13. The first die pad 14 is located on the x2-side of the first direction x, with respect to the first outer portion 11. In other words, the first outer portion 11 is located on the x1-side of the first direction x, with respect to the first die pad 14. The center of the first die pad 14 in the second direction y is located on the y2-side of the second direction y, with respect to the center of the first outer portion 11 in the second direction y. In other words, in the second direction y, the center of the first outer portion 11 is located on the y1-side of the second direction y, with respect to the center of the first die pad 14. In this embodiment, as shown in FIG. 2, the entirety of the first basal portion 112 is deviated from the first die pad 14, as viewed in the first direction x. The first outer portion 11 is located on the outer side of the second direction y (y1-side of the second direction y), with respect to the first die pad 14. Instead, a part of the first basal portion 112 may overlap with the first die pad 14, as viewed in the first direction x. Alternatively, the entirety of the first basal portion 112 may overlap with the first die pad 14, as viewed in the first direction x. The first die pad 14 includes a main face 141, a back face 142, a first side face 143, and a second side face 144.

The main face 141 and the back face 142 are spaced apart from each other, in the thickness direction z. The main face 141 is oriented upward in the thickness direction z, and the back face 142 is oriented downward in the thickness direction z. The first side face 143 is continuous with the main face 141 and the back face 142. The first side face 143 is oriented to the side on which the first outer portion 11 is located (x1-side of the first direction x), in the first direction x. The first side face 143 extends in the second direction y, in a plan view.

The second side face 144 is continuous with the main face 141 and the back face 142. The second side face 144 is oriented to the side on which the first outer portion 11 is located (y1-side of the second direction y), in the second direction y. The second side face 144 extends in the first direction x, in a plan view. The first connecting portion 13 is continuous with the second side face 144. The first connecting portion 13 is continuous with the central portion of the second side face 144, in the first direction x. In this embodiment, the first connecting portion 13 is inclined with respect to the first direction x, in a plan view. The inclination angle of the first connecting portion 13 with respect to the first direction x is not specifically limited. However, it is not mandatory that the first connecting portion 13 is inclined with respect to the first direction x, in a plan view.

In the illustrated example, the first die pad 14 has a rectangular shape, in a plan view. Here, regarding the four corners of the first die pad 14, one of the four corners of the first die pad 14 is, in the illustrated example, protruding outward in the first direction x or second direction y. In the present disclosure, such a generally rectangular shape as a whole, though not rectangular in a strict sense, will also be defined as a rectangular shape.

The first die pad 14 includes a first corner portion 149a. The first corner portion 149a is, among the four corners of the first die pad 14 in a plan view, located on the x2-side of the first direction x, and y2-side of the second direction y. The first corner portion 149a is farthest from the first outer portion 11, among the four corners of the first die pad 14. In the illustrated example, the corner portion located on the x1-side of the first direction x and y2-side of the second direction y, among the four corners of the first die pad 14, is protruding to the x1-side of the first direction x.

A thickness of the first lead 1 configured as above in the thickness direction z (first thickness t1) may be, for example, between 0.2 mm and 0.3 mm, both ends inclusive (see FIG. 10).

The second lead 2 includes a second outer portion 21 and a second inner portion 22. The second outer portion 21 and the second inner portion 22 are integrally formed, so as to be continuous with each other. The boundary between the second outer portion 21 and the second inner portion 22 overlaps with the peripheral edge of the sealing resin 7, in a plan view.

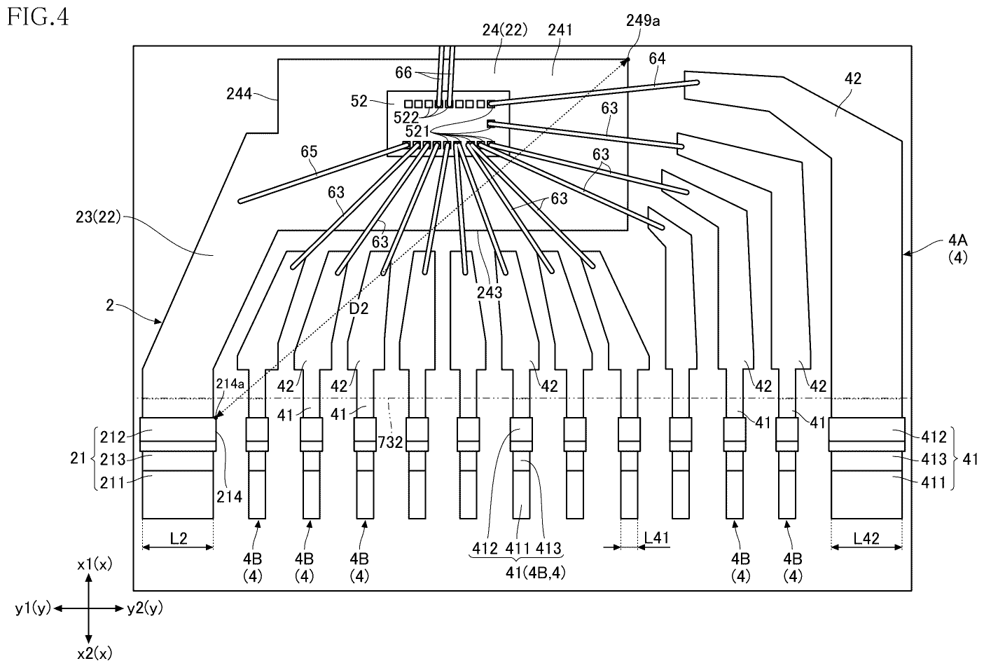

The second outer portion 21 corresponds to the portion of the second lead 2 exposed from the sealing resin 7. The second outer portion 21 is protruding from the sealing resin 7 to the x2-side of the first direction x (opposite side of the first outer portion 11 in the first direction x). The second outer portion 21 has a rectangular shape, having the longer sides extending in the first direction x, in a plan view. The second outer portion 21 is bent in a gullwing shape, as viewed in the second direction y. A second length L2 (see FIG. 4) of the second outer portion 21 in the second direction y is not specifically limited, but may be, for example, between 0.1 mm and 1.5 mm, both ends inclusive. The second outer portion 21 overlaps with the first outer portion 11, as viewed in the first direction x. Although the second length L2 of the second outer portion 21 is equal to the first length L1 of the first outer portion 11 in this embodiment, the second length L2 and the first length L1 may be different from each other. The second outer portion 21 includes a second mounting portion 211, a second basal portion 212, and a second intermediate portion 213.

The second mounting portion 211 corresponds to the distal end portion of the second outer portion 21. When the electronic device A1 is mounted on a circuit board, the second mounting portion 211 is joined to the circuit board. As shown in FIG. 1 and FIG. 2, the second mounting portion 211 is located on the end portion on the opposite side of the sealing resin 7, in the first direction x. Accordingly, the second mounting portion 211 is located more distant from the sealing resin 7 in the first direction x, than are the second basal portion 212 and the second intermediate portion 213. The second mounting portion 211 is located on the lower side in the thickness direction z, with respect to the second basal portion 212. The second mounting portion 211 is located at the same position as the first mounting portion 111, in the thickness direction z.

The second basal portion 212 corresponds to the basal portion of the second outer portion 21. As shown in FIG. 1 and FIG. 2, the second basal portion 212 is located at the end portion of the second outer portion 21 closest to the sealing resin 7, in the first direction x. In other words, the second basal portion 212 is located closer to the sealing resin 7 in the first direction x, than are the second mounting portion 211 and the second intermediate portion 213. The second basal portion 212 is located on the upper side of the second mounting portion 211 in the thickness direction z, and protruding from the central portion of the sealing resin 7 in the thickness direction z. The second basal portion 212 is located at the same position as the first basal portion 112, in the thickness direction z.

The second intermediate portion 213 is continuous with the second mounting portion 211 and the second basal portion 212. The second intermediate portion 213 is inclined with respect to the second mounting portion 211 and the second basal portion 212, as viewed in the second direction y. In this embodiment, the second intermediate portion 213 is inclined with respect to the thickness direction z.

In this embodiment, the second outer portion 21 includes a second cutting mark 214. The second cutting mark 214 is formed, when the second outer portion 21 is formed from the lead frame 9 to be subsequently described, by cutting a part of the lead frame 9. The second cutting mark 214 is oriented to the y2-side of the second direction y, and formed so as to stride over the second basal portion 212 and the second intermediate portion 213. The second cutting mark 214 is higher in surface roughness, than the remaining portions of the second outer portion 21. In addition, the second cutting mark 214 is slightly protruding toward the y2-side of the second direction y, with respect to the remaining faces of the second outer portion 21 oriented to the y2-side of the second direction y. In the drawings, the extent of protrusion of the second cutting mark 214, to the y2-side of the second direction y, is exaggerated.

The second inner portion 22 corresponds to the portion of the second lead 2 covered with the sealing resin 7. The second inner portion 22 is continuous from the second outer portion 21, and extends toward the inner region of the sealing resin 7. The second inner portion 22 includes a second connecting portion 23 and a second die pad 24.

The second connecting portion 23 extends from the second outer portion 21 toward the inner region of the sealing resin 7. The second connecting portion 23 is continuous with the second die pad 24. In other words, the second connecting portion 23 is connecting the second inner portion 22 and the second die pad 24.

The second die pad 24 supports the second electronic component 52, when the second electronic component 52 is mounted thereon. The second connecting portion 23 is connected to the second die pad 24, and the second die pad 24 is supported by the second connecting portion 23. The second die pad 24 is spaced apart from the first die pad 14. The first die pad 14 and the second die pad 24 are aligned along the first direction x, and the second die pad 24 is located on the x2-side of the first direction x, with respect to the first die pad 14. The second die pad 24 is located on the x1-side of the first direction x, with respect to the second outer portion 21. In other words, the second outer portion 21 is located on the x2-side of the first direction x, with respect to the second die pad 24. The center of the second die pad 24 in the second direction y is located on the y2-side of the second direction y, with respect to the center of the second outer portion 21 in the second direction y. In other words, in the second direction y, the center of the second outer portion 21 is located on the y1-side of the second direction y, with respect to the center of the second die pad 24. In this embodiment, as shown in FIG. 2, the entirety of the second basal portion 212 is deviated from the second die pad 24, as viewed in the first direction x. The second outer portion 21 is located on the outer side in the second direction y (y1-side of the second direction y), with respect to the second die pad 24. Instead, a part of the second basal portion 212 may overlap with the second die pad 24, as viewed in the first direction x. Alternatively, the entirety of the second basal portion 212 may overlap with the second die pad 24, as viewed in the first direction x. The second die pad 24 includes a main face 241, a back face 242, a third side face 243, and a fourth side face 244.

The main face 241 and the back face 242 are spaced apart from each other, in the thickness direction z. The main face 241 is oriented upward in the thickness direction z, and the back face 242 is oriented downward in the thickness direction z. The third side face 243 is continuous with the main face 241 and the back face 242. The third side face 243 is oriented to the side on which the second outer portion 21 is located (x2-side of the first direction x), in the first direction x. The third side face 243 extends in the second direction y, in a plan view.

The fourth side face 244 is continuous with the main face 241 and the back face 242. The fourth side face 244 is oriented to the side on which the second outer portion 21 is located (y1-side of the second direction y), in the second direction y. The fourth side face 244 extends in the first direction x, in a plan view. The second connecting portion 23 is continuous with the fourth side face 244. The second connecting portion 23 is continuous with the x2-side of the first direction x of the fourth side face 244, in the first direction x. In this embodiment, the second connecting portion 23 is inclined with respect to the first direction x, in a plan view. The inclination angle of the second connecting portion 23 with respect to the first direction x is not specifically limited. However, it is not mandatory that the second connecting portion 23 is inclined with respect to the first direction x, in a plan view.

In the illustrated example, the second die pad 24 has a rectangular shape, in a plan view. The second die pad 24 includes a second corner portion 249a. The second corner portion 249a is, among the four corners of the second die pad 24 in a plan view, located on the x1-side of the first direction x, and y2-side of the second direction y. The second corner portion 249a is farthest from the second outer portion 21, among the four corners of the second die pad 24.

A thickness of the second lead 2 configured as above in the thickness direction z (second thickness t2) may be, for example, between 0.2 mm and 0.3 mm, both ends inclusive (see FIG. 10).

The third lead 3 includes a third outer portion 31 and a third inner portion 32. The third outer portion 31 and the third inner portion 32 are integrally formed, so as to be continuous with each other. The boundary between the third outer portion 31 and the third inner portion 32 overlaps with the peripheral edge of the scaling resin 7, in a plan view.

The third outer portion 31 corresponds to the portion of the third lead 3 exposed from the scaling resin 7. The third outer portion 31 is protruding from the sealing resin 7, to the x1-side of the first direction x (same side as the first outer portion 11). The third outer portion 31 has a rectangular shape, having the longer sides extending in the first direction x, in a plan view. Although the plan-view shape of the third outer portion 31 is congruent with that of the first outer portion 11 in this embodiment, it is not mandatory that the plan-view shapes are congruent with each other. The third outer portion 31 is bent in a gullwing shape, as viewed in the second direction y. A third length L3 (see FIG. 3) of the third outer portion 31 in the second direction y is not specifically limited, but may be, for example, between 0.1 mm and 1.5 mm, both ends inclusive. Although the third length L3 of the third outer portion 31 is equal to the first length L1 of the first outer portion 11 in this embodiment, the third length L3 and the first length L1 may be different from each other. The third outer portion 31 includes a third mounting portion 311, a third basal portion 312, and a third intermediate portion 313.

The third mounting portion 311 corresponds to the distal end portion of the third outer portion 31. When the electronic device A1 is mounted on a circuit board, the third mounting portion 311 is joined to the circuit board. As shown in FIG. 1 and FIG. 2, the third mounting portion 311 is located on the end portion on the opposite side of the sealing resin 7, in the first direction x. Accordingly, the third mounting portion 311 is located more distant from the sealing resin 7 in the first direction x, than the third basal portion 312 and the third intermediate portion 313. The third mounting portion 311 is located on the lower side in the thickness direction z, with respect to the third basal portion 312. The third mounting portion 311 is located at the same position as the first mounting portion 111, in the thickness direction z.

The third basal portion 312 corresponds to the basal portion of the third outer portion 31. As shown in FIG. 1 and FIG. 2, the third basal portion 312 is located at the end portion of the third outer portion 31 closest to the sealing resin 7, in the first direction x. In other words, the third basal portion 312 is located closer to the sealing resin 7 in the first direction x, than are the third mounting portion 311 and the third intermediate portion 313. The third basal portion 312 is located on the upper side of the third mounting portion 311 in the thickness direction z, and protruding from the central portion of the sealing resin 7 in the thickness direction z.

The third intermediate portion 313 is continuous with the third mounting portion 311 and the third basal portion 312. The third intermediate portion 313 is inclined with respect to the third mounting portion 311 and the third basal portion 312, as viewed in the second direction y. In this embodiment, the third intermediate portion 313 is inclined with respect to the thickness direction 2.

The third inner portion 32 corresponds to the portion of the third lead 3 covered with the sealing resin 7. The third inner portion 32 is continuous from the third outer portion 31, and extends toward the inner region of the sealing resin 7. The third inner portion 32 extends from the third outer portion 31 toward the first die pad 14, inside the sealing resin 7.

The plurality of fourth leads 4 each include a fourth outer portion 41 and a fourth inner portion 42. Accordingly, the electronic device A1 includes a plurality of fourth outer portions 41 and a plurality of fourth inner portions 42. In the following description, the plurality of fourth leads 4 may be distinctively referred to as “fourth lead 4A” and “plurality of fourth leads 4B”. The other of a pair of fourth leads 4 may be referred to as “fourth lead 4B”. The fourth lead 4A is located on the y2-side of the second direction y, with respect to the plurality of fourth leads 4B. In each of the fourth leads 4, the fourth outer portion 41 and the fourth inner portion 42 are integrally formed, so as to be continuous with each other. In each of the fourth leads 4, the boundary between the fourth outer portion 41 and the fourth inner portion 42 overlaps with the peripheral edge of the sealing resin 7, in a plan view. The fourth outer portion 41 and the fourth inner portion 42 referred to hereunder are, unless otherwise specifically noted, formed in common to each of the fourth leads 4.

The fourth outer portion 41 corresponds to the portion of each of the fourth leads 4 exposed from the sealing resin 7. The fourth outer portion 41 is protruding from the scaling resin 7 to the x2-side of the first direction x (opposite side of the first outer portion 11 and the third outer portion 31, and the same side as the second outer portion 21). The fourth outer portions 41 of the respective fourth leads 4B each have a belt-like shape, having the longer sides extending in the first direction x, in a plan view. The fourth outer portions 41 of the respective fourth leads 4B are aligned at regular intervals along the second direction y. The fourth outer portion 41 of the fourth lead 4A is located on the y2-side of the second direction y, with respect to the fourth outer portions 41 of the respective fourth leads 4B. The fourth outer portion 41 of the fourth lead 4A, has a rectangular shape, having the longer sides extending in the first direction x. The fourth outer portions 41 of the respective fourth leads 4 are bent in a gullwing shape, as viewed in the second direction y. The plurality of fourth outer portions 41 (fourth outer portions 41 of the fourth lead 4A and the plurality of fourth leads 4B) overlap with each other, as viewed in the second direction y.

A length L41 of the fourth outer portions 41 of the respective fourth leads 4B in the second direction y is not specifically limited, but may be, for example, between 0.15 mm and 0.5 mm, both ends inclusive. The length L41 of the fourth outer portions 41 of the respective fourth leads 4B in the second direction y is shorter than the first length L1 of the first outer portion 11 in the second direction y, and the second length L2 of the second outer portion 21 in the second direction y. The fourth outer portion 41 of the fourth lead 4A overlaps with the third outer portion 31, as viewed in the first direction x. A length L42 of the fourth outer portions 41 of the fourth lead 4A in the second direction y is not specifically limited, but may be, for example, between 0.1 mm and 1.5 mm, both ends inclusive. In this embodiment, the length L42 of the fourth outer portions 41 of the fourth lead 4A in the second direction y is equal to the first length L1 of the first outer portion 11 in the second direction y, the second length L2 of the second outer portion 21 in the second direction y, and the length L3 of the third outer portion 31 in the second direction y. Instead, the length L42 of the fourth outer portions 41 of the fourth lead 4A in the second direction y may be different from the first length L1 of the first outer portion 11 in the second direction y, the second length L2 of the second outer portion 21 in the second direction y, and the length L3 of the third outer portion 31 in the second direction y. The fourth outer portion 41 includes a fourth mounting portion 411, a fourth basal portion 412, and a fourth intermediate portion 413. The fourth mounting portion 411, the fourth basal portion 412, and the fourth intermediate portion 413 referred to hereunder are, unless otherwise specifically noted, formed in common to each of the fourth outer portions 41 of the fourth lead 4.

The fourth mounting portion 411 corresponds to the distal end portion of the fourth outer portion 41. When the electronic device A1 is mounted on a circuit board, the fourth mounting portion 411 is joined to the circuit board. As shown in FIG. 1 and FIG. 2, the fourth mounting portion 411 is located on the end portion on the opposite side of the sealing resin 7, in the first direction x. Accordingly, the fourth mounting portion 411 is located more distant from the sealing resin 7 in the first direction x, than are the fourth basal portion 412 and the fourth intermediate portion 413. The fourth mounting portion 411 is located on the lower side in the thickness direction z, with respect to the fourth basal portion 412. The plurality of fourth mounting portions 411 are located at the same position, in the thickness direction z. The fourth mounting portions 411 of the respective fourth leads 4B are aligned at regular intervals, along the second direction y. The fourth mounting portion 411 of the fourth lead 4A is located adjacent to the plurality of fourth mounting portions 411 of the fourth leads 4B, in the second direction y, on the y2-side of the second direction y.

The fourth basal portion 412 corresponds to the basal portion of the fourth outer portion 41. As shown in FIG. 1 and FIG. 2, the fourth basal portion 412 is located at the end portion of the fourth outer portion 41 closest to the sealing resin 7, in the first direction x. In other words, the fourth basal portion 412 is located closer to the sealing resin 7 in the first direction x, than are the fourth basal portion 412 and the fourth intermediate portion 413. The fourth basal portion 412 is located on the upper side of the fourth mounting portion 411 in the thickness direction z, and protruding from the central portion of the sealing resin 7 in the thickness direction z. The plurality of fourth basal portions 412 are located at the same position, in the thickness direction z.

The fourth intermediate portion 413 is continuous with the fourth mounting portion 411 and the fourth basal portion 412. The fourth intermediate portion 413 is inclined with respect to the fourth mounting portion 411 and the fourth basal portion 412, as viewed in the second direction y. In this embodiment, the fourth intermediate portion 413 is inclined with respect to the thickness direction z.

The fourth inner portion 42 is the portion of the corresponding fourth lead 4 covered with the sealing resin 7. The fourth inner portion 42 is continuous with the fourth outer portion 41, and extends therefrom toward the inner region of the sealing resin 7. In each of the fourth leads 4, the fourth inner portion 42 extends from the fourth outer portion 41 toward the second die pad 24, inside the sealing resin 7.

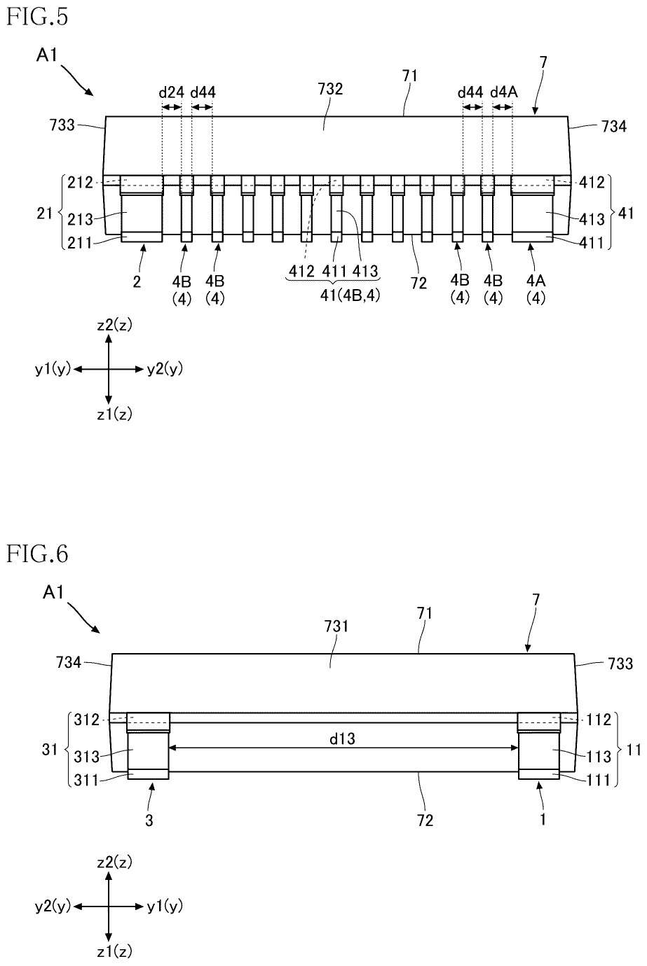

In the electronic device A1, the first outer portion 11 and the third outer portion 31 are spaced apart from each other in the second direction y, by a clearance d13 (see FIG. 6). The fourth outer portions 41 of the respective fourth leads 4B are aligned along the second direction y, with a clearance d44 (see FIG. 5) between each other. The clearance d13 between the first outer portion 11 and the third outer portion 31 in the second direction y (see FIG. 6) is larger than the clearance d44 in the second direction y (see FIG. 5) between the adjacent ones of the fourth outer portions 41 aligned along the second direction y. For example, the clearance d13 may be between 10 times and 20 times as long as the clearance d44, both ends inclusive. In this embodiment, the clearance d13 is for example between 5 mm and 10 mm, both ends inclusive, and the clearance d44 is for example between 0.25 mm and 5 mm, both ends inclusive. Here, when the potential difference between the first outer portion 11 and the third outer portion 31 is approximately 800 V, it is preferable make the clearance d13 equal to or larger than 4 mm, to prevent a short-circuit between the first outer portion 11 and the third outer portion 31. A clearance d24 in the second direction y (see FIG. 5) between the second outer portion 21 and the fourth outer portion 41 of the fourth lead 4B adjacent to the second outer portion 21, and a clearance d4A in the second direction y (see FIG. 5) between the fourth outer portion 41 of the fourth lead 4A and the fourth outer portion 41 of the fourth lead 4B adjacent to the former fourth outer portion 41, are each equal to the clearance d44.

In the electronic device A1, the shape of each of the first die pad 14, the second die pad 24, the first inner portion 12, the second inner portion 22, the third inner portion 32, and the plurality of fourth inner portion 42, and the positional relation among the mentioned components, are not limited to the illustrated examples, but may be modified as desired, depending on the specification of the electronic device A1.

The first electronic component 51 and the second electronic component 52 are the elements that realize electrical functions in the electronic device A1. The specific function of the first electronic component 51 and the second electronic component 52 is in no way limited but, in this embodiment, the first electronic component 51 and the second electronic component 52 are configured to detect a voltage.

The first electronic component 51 is bonded to the first die pad 14 with a non-illustrated bonding material (e.g., solder or sintered silver), thus to be mounted on the first die pad 14. In this embodiment, the first electronic component 51 outputs a first signal according to the potential of the first lead 1, and a first signal according to the potential of the third lead 3, to the second electronic component 52. The first electronic component 51 includes a plurality of electrodes 511, 512, and 513, located on the upper face in the thickness direction z.

The second electronic component 52 is bonded to the second die pad 24 with a non-illustrated bonding material (e.g., solder or sintered silver), thus to be mounted on the second die pad 24. In this embodiment, the second electronic component 52 receives the input of the first signal and the second signal from the first electronic component 51, and outputs a third signal according to the potential difference between the first lead 1 and the third lead 3. Thus, the second electronic component 52 outputs a detection signal (third signal) of the voltage applied between the first lead 1 and the third lead 3. The second electronic component 52 includes a plurality of electrodes 521 and 522, located on the upper face in the thickness direction z.

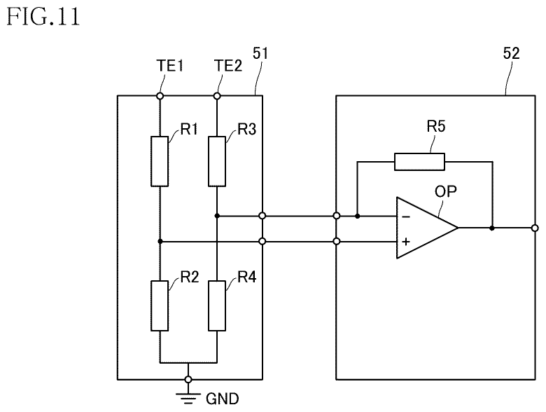

In the electronic device A1, the first electronic component 51 and the second electronic component 52 have a circuit configuration, for example shown in FIG. 11. As shown in FIG. 11, the first electronic component 51 includes a plurality of resistor elements R1 to R4, and the second electronic component 52 includes an operational amplifier OP and a resistor element R5. Here, the circuit configuration of the first electronic component 51 and the second electronic component 52 is not limited to the example shown in FIG. 11.

Two resistor elements R1 and R2 are connected in series to each other. The two resistor elements R1 and R2 divides the voltage of the terminal TE1 (difference between the potential of the terminal TE1 and the reference potential of GND). In this embodiment, the terminal TE1 corresponds to the plurality of electrodes 512. The connection point of the two resistor elements R1 and R2 is connected to the non-inverting input terminal of the operational amplifier OP. Two resistor elements R3 and R4 are connected in series to each other. The two resistor elements R3 and R4 divides the voltage of the terminal TE2 (difference between the potential of the terminal TE2 and the reference potential of GND). In this embodiment, the terminal TE2 corresponds to the plurality of electrodes 511. The connection point of the two resistor elements R3 and R4 is connected to the inverting input terminal of the operational amplifier OP. When the electronic device A1 detects the voltage of a battery mounted in an electric vehicle, one of the terminal TE1 and the terminal TE2 is electrically connected to the high-potential terminal of the battery, and the other is electrically connected to the low-potential terminal.

The operational amplifier OP receives the input of the first signal according to the potential of the terminal TE1 (in this embodiment, signal of the divided voltage of the terminal TE1), and the second signal according to the potential of the terminal TE2 (in this embodiment, signal of the divided voltage of the terminal TE2), and outputs the third signal according to the potential difference between the terminal TE1 and the terminal TE2. The resistor element R5 is an element for determining the amplification gain of the operational amplifier OP (feedback resistor). An end of the resistor element R5 is connected to the inverting input terminal of the operational amplifier OP, and the other end is connected to the output terminal of the operational amplifier OP. Here, the second electronic component 52 may be without the resistor element R5.

The plurality of connection members 61 to 66 each electrically connect between positions spaced apart from each other. In the illustrated example, the plurality of connection members 61 to 66 are bonding wires. The plurality of connection members 61 to 66 may each be a plate-shaped metal material, instead of the bonding wire. The plurality of connection members 61 to 66 each include one of Au, aluminum (Al), and Cu.

The connection member 61 is bonded to the electrode 511 of the first electronic component 51 and the second inner portion 22, as shown in FIG. 2, and electrically connecting the first electronic component 51 and the third lead 3. Accordingly, the third outer portion 31 of the third lead 3 is electrically continuous with the first electronic component 51, via the third inner portion 32 and the connection member 61.

The connection member 62 is bonded to the electrode 512 of the first electronic component 51 and the first connecting portion 13 (first inner portion 12), as shown in FIG. 2, and electrically connecting the first electronic component 51 and the first lead 1. Accordingly, the first outer portion 11 of the first lead 1 is electrically continuous with the first electronic component 51, via the first connecting portion 13 and the connection member 62.

The plurality of connection members 63 are each bonded to the electrode 521 of the second electronic component 52 and one of the fourth inner portions 42 of the respective fourth leads 4B, as shown in FIG. 2, and electrically connecting the second electronic component 52 and one of the plurality of fourth leads 4B. Accordingly, the fourth outer portions 41 of the respective fourth leads 4B are each electrically continuous with the second electronic component 52, via the corresponding fourth inner portion 42 and the corresponding connection member 63.

The connection member 64 is bonded to the electrode 521 of the second electronic component 52 and the fourth inner portion 42 of the fourth lead 4A, as shown in FIG. 2, and electrically connecting the second electronic component 52 and the fourth lead 4A. Accordingly, the fourth outer portion 41 of the fourth lead 4A is electrically continuous with the second electronic component 52, via the fourth inner portion 42 of the fourth lead 4A and the connection member 64.

The connection member 65 is bonded to the electrode 521 of the second electronic component 52 and the second connecting portion 23 (second inner portion 22), as shown in FIG. 2, and electrically connecting the second electronic component 52 and the second lead 2. Accordingly, the second outer portion 21 of the second lead 2 is electrically continuous with the second electronic component 52, via the second connecting portion 23 and the connection member 65.

The plurality of connection members 66 are each bonded to the electrode 513 of the first electronic component 51 and the electrode 522 of the second electronic component 52, as shown in FIG. 2, and electrically connecting the first electronic component 51 and the second electronic component 52. Accordingly, the plurality of connection members 66 each serve as the transmission path of the first signal and the second signal.

The sealing resin 7 covers a part of each of the first lead 1, the second lead 2, the third lead 3, and the plurality of fourth leads 4, the first electronic component 51 and the second electronic component 52, and the plurality of connection members 61 to 66. The scaling resin 7 includes, for example, an insulative material such as an epoxy resin. Preferably, the scaling resin 7 may be formed of a resin material having a comparative tracking index (CTI) of 600 V or higher. The forming method of the sealing resin 7 is not specifically limited, but may be, for example, a molding method. The sealing resin 7 is formed, for example, in a rectangular cuboid shape. The size of the sealing resin 7 along the second direction y is for example between 5 mm and 10 mm, both ends inclusive, and the size along the first direction x is for example between 3 mm and 13 mm, both ends inclusive. The sealing resin 7 includes a resin main face 71, a resin back face 72, a first resin side face 731, a second resin side face 732, a third resin side face 733, and a fourth resin side face 734.

The resin main face 71 and the resin back face 72 are spaced apart from each other, in the thickness direction z. The resin main face 71 is oriented to the 22-side of the thickness direction z, and the resin back face 72 is oriented to the z1-side of the thickness direction z. The resin main face 71 corresponds to the upper face of the sealing resin 7, and the resin back face 72 corresponds to the lower face of the sealing resin 7.

The first resin side face 731 and the second resin side face 732 are spaced apart from each other, in the first direction x. The first resin side face 731 is oriented to the x1-side of the first direction x, and the second resin side face 732 is oriented to the x2-side of the first direction x. The third resin side face 733 and the fourth resin side face 734 are spaced apart from each other, in the second direction y. The third resin side face 733 is oriented to the y1-side of the second direction y, and the fourth resin side face 734 is oriented to the y2-side of the second direction y.

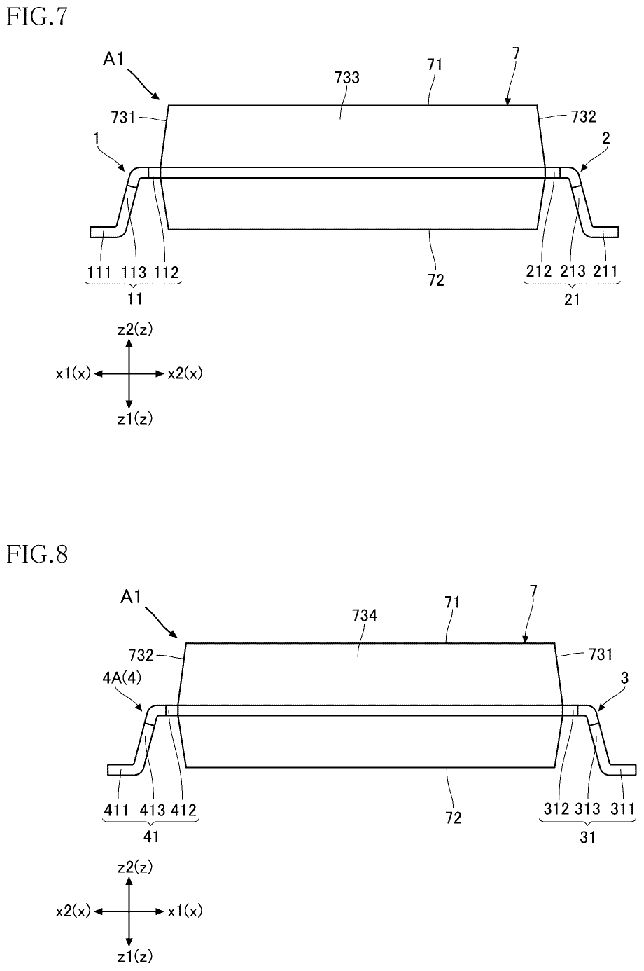

As shown in FIG. 1 to FIG. 3, and FIG. 6 to FIG. 10, the first outer portion 11 and the third outer portion 31 are each protruding from the first resin side face 731. As shown in FIG. 1, FIG. 2, FIG. 4, FIG. 5, and FIG. 7 to FIG. 10, the second outer portion 21 of the second lead 2 and the fourth outer portions 41 of the fourth lead 4 are each protruding from the second resin side face 732.

In the electronic device A1 configured as above, a ratio of a first distance D1 (see FIG. 3) between a first end 114a of the first cutting mark 114 in the first outer portion 11, on the x2-side of the first direction x, and a first corner portion 149a of the first die pad 14, to a first length L1 (see FIG. 3) of the first outer portion 11 in the second direction y, in a plan view, is defined as follows. Specifically, the first distance D1 is set to be equal to or shorter than 10.8 times as long as the first length L1 (L1/D1≤10.8). For example, the first distance D1 from the first end 114a to the first corner portion 149a is between 5.5 times and 10.8 times as long, both ends inclusive, as the first length L1 of the first outer portion 11 in the second direction y. An example of the specific length of the first distance D1 is between 1.1 mm and 2.2 mm, both ends inclusive.

In the electronic device A1, in addition, a ratio of a second distance D2 (see FIG. 4) between a second end 214a of the second cutting mark 214 in the second outer portion 21, on the x1-side of the first direction x, and a second corner portion 249a of the second die pad 24, to a second length L2 (see FIG. 4) of the second outer portion 21 in the second direction y, in a plan view, is defined as follows. Specifically, the second distance D2 is set to be equal to or shorter than 10.8 times as long as the second length L2 (L2/D2≤10.8). For example, the second distance D2 from the second end 214a to the second corner portion 249a is between 5.5 times and 10.8 times as long, both ends inclusive, as the second length L2 of the second outer portion 21 in the second direction y. An example of the specific length of the second distance D2 is between 1.1 mm and 2.2 mm, both ends inclusive.

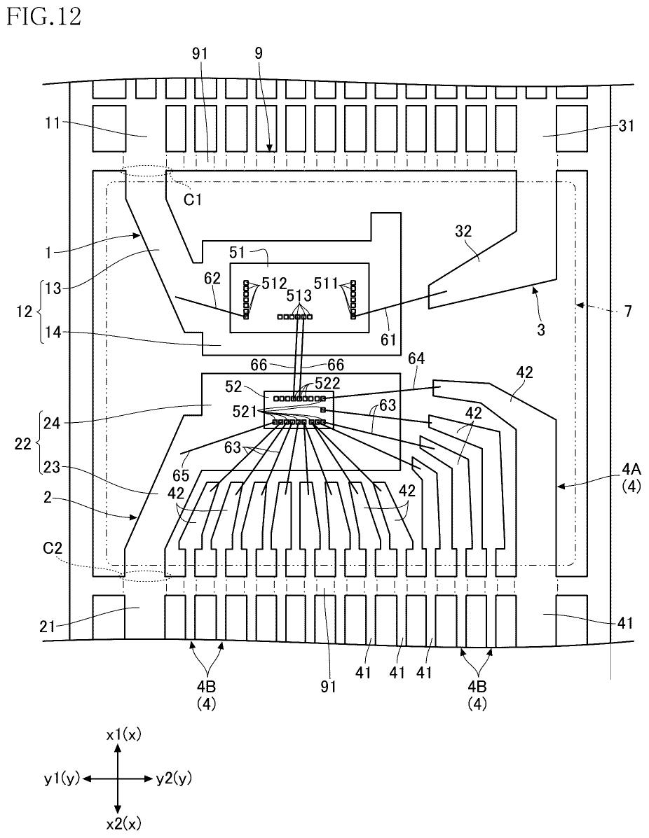

FIG. 12 illustrates a step in the manufacturing process of the electronic device A1. FIG. 12 represents a state before the formation of the sealing resin 7. In the manufacturing process of the electronic device A1, as shown in FIG. 12, the first lead 1, the second lead 2, the third lead 3, and the plurality of fourth leads 4 are connected to each other, via tie bars 91, and included in a single lead frame 9. The tie bars 91 are, for example, respectively connected to the first outer portion 11 of the first lead 1, the second outer portion 21 of the second lead 2, the third outer portion 31 of the third lead 3, and the fourth outer portions 41 of the respective fourth leads 4. In the lead frame 9 processed as above, the first inner portion 12 is supported by the tie bar 91, at a connection point C1 shown in FIG. 12. Likewise, the second inner portion 22 is supported by the tie bar 91, at a connection point C2 shown in FIG. 12.

In the manufacturing process of the electronic device A1, the first electronic component 51 and the second electronic component 52 are mounted (bonded) and the connection members 61 to 66 are formed (wire bonding), on the lead frame 9 shown in FIG. 12. Then the sealing resin 7 is formed, for example through a molding process. Thereafter, the first lead 1, the second lead 2, the third lead 3, and the plurality of fourth leads 4 are cut away from the tie bars 91, and the first outer portion 11, the second outer portion 21, the third outer portion 31, and the plurality of fourth outer portion 41 are subjected to a bending process. Thus, the electronic device A10 can be obtained.

Hereunder, the working of the electronic device A1 will be described.

In the electronic device A1, the center of the first outer portion 11 is located on the y1-side of the second direction y with respect to the center of the first die pad 14, in the second direction y. In a plan view, the first distance D1 between the first end 114a of the first cutting mark 114 in the first outer portion 11, on the x2-side of the first direction x, and the first corner portion 149a of the first die pad 14, is set to be equal to or shorter than 10.8 times as long as the first length L1 of the first outer portion 11 in the second direction y (L1/D1≤10.8).

As shown in FIG. 12, in the manufacturing process of the electronic device A1, the first inner portion 12 is supported by the tie bar 91 in a cantilever form, at the connection point C1. The first inner portion 12 includes the first connecting portion 13 and the first die pad 14 continuous therefrom, and the first die pad 14 is supported by the tie bar 91 via the first connecting portion 13. With such configuration, the connection point C1 is subjected to a bending moment, owing to the self-weight of the first inner portion 12 (first connecting portion 13 and first die pad 14). Whereas the connection point C1 is more likely to be deformed (bent), the larger the bending moment is, the bending moment tends to be larger, the more distant from the connection point C1 the first die pad 14 is. On the other hand, increasing the length in the second direction y, of the connection point C1 where the first inner portion 12 is continuous with the tie bar 91, leads to an increase in sectional area of the connection point C1, which results in increased strength thereof. Therefore, the deformation at the connection point C1 can be suppressed.

According to the studies pursued by the present inventor, it has been found out that the deformation of the first inner portion 12 at the connection point C1 in the lead frame 9 can be suppressed, when the first distance D1 between the first end 114a of the first cutting mark 114 in the first outer portion 11, on the x2-side of the first direction x, and the first corner portion 149a of the first die pad 14, is equal to or shorter than 10.8 times as long as the first length L1 of the first outer portion 11 in the second direction y, as described above. The first corner portion 149a is located, among the four corners of the first die pad 14 in a plan view, on the x2-side of the first direction x, and on the y2-side of the second direction y. The first corner portion 149a is farthest from the first outer portion 11 (connection point C1) among the four corners of the first die pad 14. The occurrence of the deformation of the lead frame 9 during the manufacturing of the electronic device A1 can be predicted, on the basis of the relation between the first distance D1, from the first end 114a of the first cutting mark 114, closest to the first corner portion 149a in the region of the connection point C1 in a plan view, to the first corner portion 149a, and the first length L1 of the first outer portion 11 corresponding to the size of the connection point C1 in the second direction y, and therefore the designing of the strength of the lead frame 9 in the electronic device A1 can be simplified. As result, it has been determined, in the electronic device A1, to set the first distance D1 between the first end 114a of the first cutting mark 114 in the first outer portion 11, on the x2-side of the first direction x, and the first corner portion 149a of the first die pad 14, to be equal to or shorter than 10.8 times as long as the first length L1 of the first outer portion 11 in the second direction y, in a plan view. Such a configuration suppresses the deformation of the lead frame 9 (first lead 1), during the manufacturing of the electronic device A1.

In the electronic device A1, the center of the second outer portion 21 is located on the y1-side of the second direction y with respect to the center of the second die pad 24, in the second direction y. In a plan view, the second distance D2 between the second end 214a of the second cutting mark 214 in the second outer portion 21, on the x1-side of the first direction x, and the second corner portion 249a of the second die pad 24, is set to be equal to or shorter than 10.8 times as long as the second length L2 of the second outer portion 21 in the second direction y (L2/D2≤10.8).

As shown in FIG. 12, in the manufacturing process of the electronic device A1, the second inner portion 22 is supported by the tie bar 91 in a cantilever form, at the connection point C2. The second inner portion 22 includes the second connecting portion 23 and the second die pad 24 continuous therefrom, and the second die pad 24 is supported by the tie bar 91 via the second connecting portion 23. With such configuration, the connection point C2 is subjected to a bending moment, owing to the self-weight of the second inner portion 22 (second connecting portion 23 and second die pad 24). Whereas the connection point C2 is more likely to be deformed (bent), the larger the bending moment is, the bending moment tends to be larger, the more distant from the connection point C2 the second die pad 24 is. On the other hand, increasing the length in the second direction y, of the connection point C2 where the second inner portion 22 is continuous with the tie bar 91, leads to an increase in sectional area of the connection point C2, which results in increased strength thereof. Therefore, the deformation at the connection point C2 can be prevented.

Regarding the second lead 2, the setting that the second distance D2 is equal to or shorter than 10.8 times as long as the second length L2 (L2/D2≤10.8) is similar to the setting with the first lead 1, that the first distance D1 is equal to or shorter than 10.8 times as long as the first length L1 (L1/D1≤10.8). Therefore, the deformation of the lead frame 9 (second lead 2) can also be suppressed, during the manufacturing of the electronic device A1, like in the case of the first lead 1.

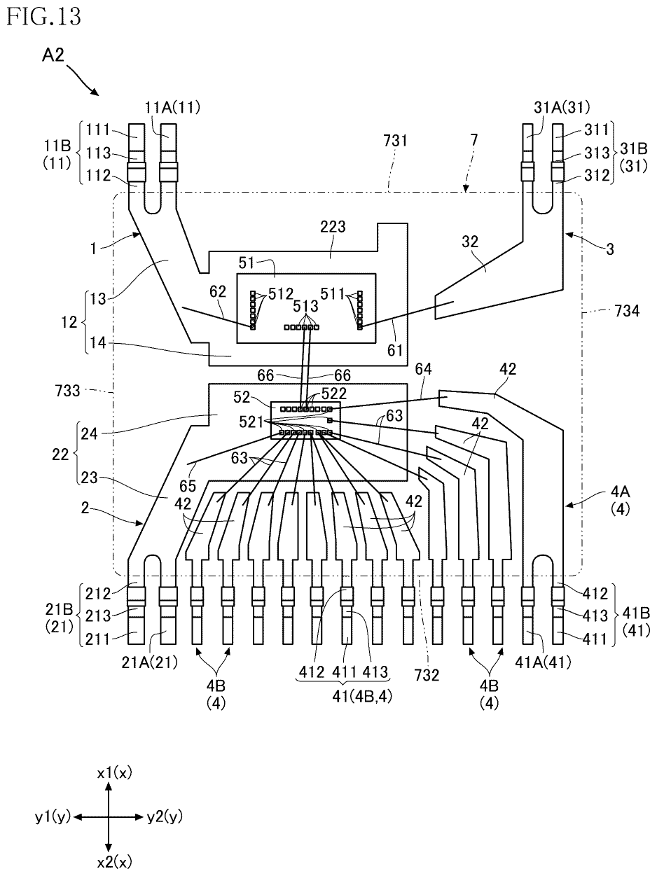

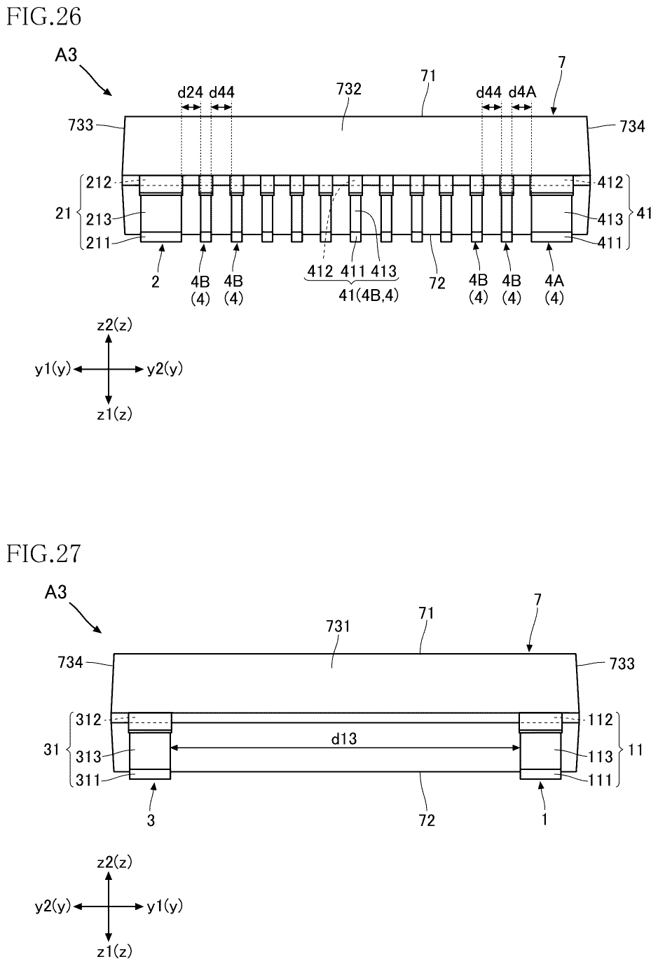

FIG. 13 to FIG. 27 illustrate other embodiments and variations thereof, of the present disclosure. In these drawings, the elements same as or similar to those of the first embodiment are given the same numeral as in the first embodiment, and the description of such elements will not be repeated. Here, the configuration of each elements in the embodiments and variations may be combined as desired, unless technical contradiction arises.

### Second Embodiment

FIG. 13 to FIG. 17 illustrate an electronic device A2 according to a second embodiment of the present disclosure. The electronic device A2 according to this embodiment is different from the electronic device A1, in the configuration of the first lead 1, the second lead 2, the third lead 3, and the fourth lead 4 (fourth lead 4A).

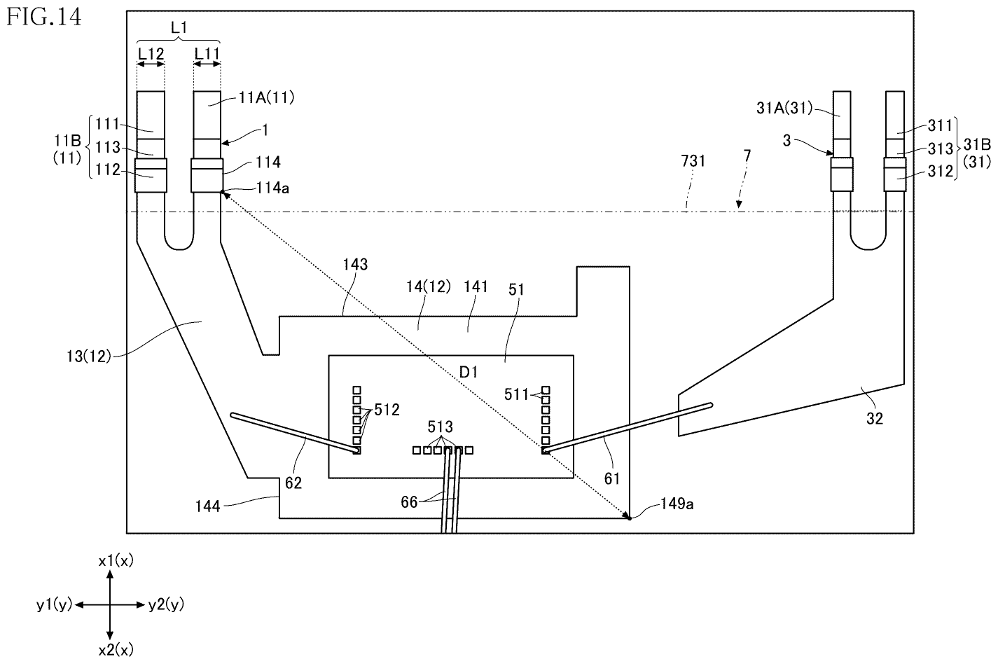

As shown in FIG. 13, FIG. 14, and FIG. 17, the first outer portion 11 of the electronic device A2 includes two portions, namely a first portion 11A and a second portion 11B, spaced apart from each other in the second direction y. The first portion 11A and the second portion 11B each include the first mounting portion 111, the first basal portion 112, and the first intermediate portion 113.

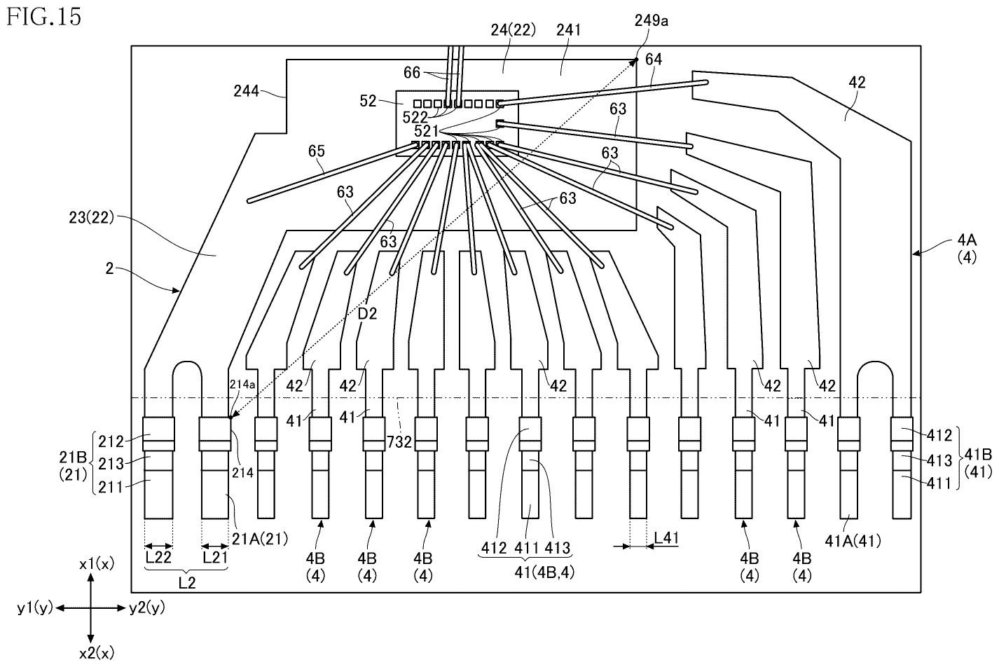

As shown in FIG. 14 and FIG. 15, respective lengths L11 and L12 of the first portion 11A and the second portion 11B in the second direction y are longer than a length L41 of the fourth outer portions 41 of the respective fourth leads 4B in the second direction y. The plurality of fourth leads 4B of the electronic device A2 exemplify the “terminal lead” in the present disclosure. In addition, the fourth outer portions 41 of the respective fourth leads 4B each correspond to the “terminal lead outer portion” in the present disclosure, and the fourth inner portions 42 of the respective fourth leads 4B each correspond to the “terminal lead inner portion” in the present disclosure.

As shown in FIG. 17, the first portion 11A and the second portion 11B are adjacent to each other in the second direction y, with a clearance d11 therebetween. Although the clearance d11 is narrower than the clearance d44 in the illustrated example, these clearances may be equal to each other. Because of such a configuration, the first inner portion 12 of the first lead 1 is split into two portions, on the end portion continuous with the first outer portion 11 (first portion 11A and second portion 11B). Thus, since the first portion 11A and the second portion 11B are electrically connected to each other via the first inner portion 12, the first portion 11A and the second portion 11B are equipotential. In the first outer portion 11 configured as above, the first length L1 in the second direction y corresponds to the total of the length L11 of the first portion 11A in the second direction y, and the length L12 of the second portion 11B in the second direction y.

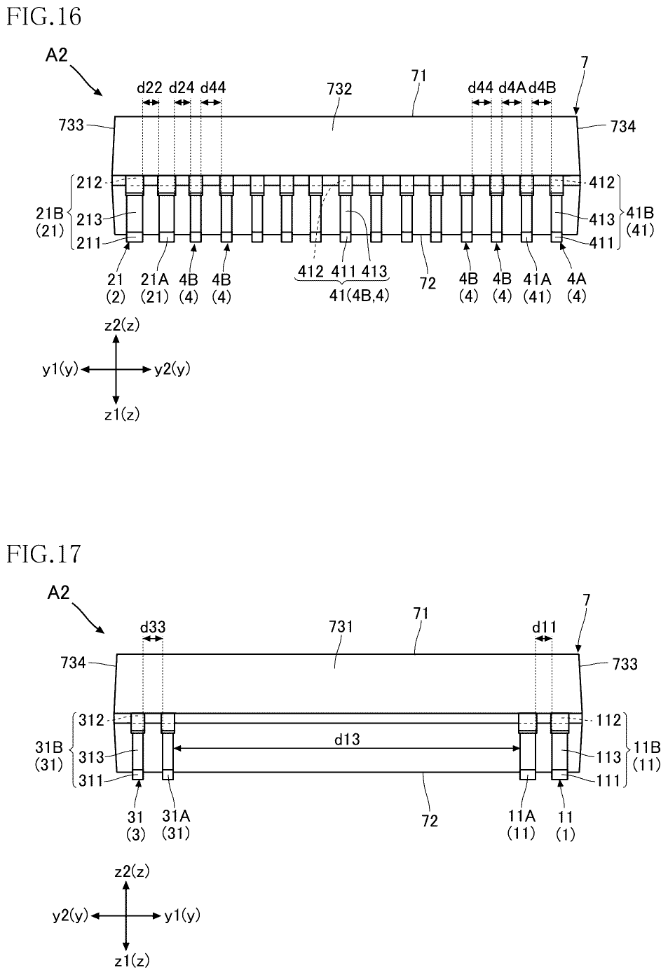

As shown in FIG. 13, FIG. 15, and FIG. 16, the second lead 2 of the electronic device A2 includes two portions, namely a fourth portion 21A and a fifth portion 21B spaced apart from each other in the second direction y. The fourth portion 21A and the fifth portion 21B each include the second mounting portion 211, the second basal portion 212, and the second intermediate portion 213.

As shown in FIG. 15, respective lengths L21 and L22 of the fourth portion 21A and the fifth portion 21B in the second direction y are longer than a length L41 of the fourth outer portions 41 of the respective fourth leads 4B in the second direction y. As shown in FIG. 16, the fourth portion 21A and the fifth portion 21B are adjacent to each other in the second direction y, with a clearance d22 therebetween. Although the clearance d22 is narrower than the clearance d44 in the illustrated example, these clearances may be equal to each other. Because of such a configuration, the second inner portion 22 of the second lead 2 is split into two portions, on the end portion continuous with the second outer portion 21 (fourth portion 21A and fifth portion 21B). Thus, since the fourth portion 21A and the fifth portion 21B are electrically connected to each other via the second inner portion 22, the fourth portion 21A and the fifth portion 21B are equipotential. In the second outer portion 21 configured as above, the second length L2 in the second direction y corresponds to the total of the length L21 of the fourth portion 21A in the second direction y, and the length L22 of the fifth portion 21B in the second direction y.

As shown in FIG. 13, FIG. 14, and FIG. 17, the third lead 3 of the electronic device A2 includes two portions, namely a seventh portion 31A and an eighth portion 31B spaced apart from each other in the second direction y. The seventh portion 31A and the eighth portion 31B each include the third mounting portion 311, the third basal portion 312, and the third intermediate portion 313. As shown in FIG. 17, the seventh portion 31A and the eighth portion 31B are adjacent to each other in the second direction y, with a clearance d33 therebetween. Although the clearance d33 is equal to the clearance d44 in the illustrated example, these clearances may be different from each other. Because of such a configuration, the third inner portion 32 of the third lead 3 is split into two portions, on the end portion continuous with the third outer portion 31 (seventh portion 31A and eighth portion 31B). Thus, since the seventh portion 31A and the eighth portion 31B are electrically connected to each other via the third inner portion 32, the seventh portion 31A and the eighth portion 31B are equipotential.

As shown in FIG. 13, FIG. 15, and FIG. 16, the fourth lead 4A of the electronic device A2 includes two portions, namely a ninth portion 41A and a tenth portion 41B spaced apart from each other in the second direction y. The ninth portion 41A and the tenth portion 41B each include the third mounting portion 411, the third basal portion 412, and the third intermediate portion 413. As shown in FIG. 16, the ninth portion 41A and the tenth portion 41B are adjacent to each other in the second direction y, with a clearance d4B therebetween. Although the clearance d4B is equal to the clearance d44 in the illustrated example, these clearances may be different from each other. Because of such a configuration, the fourth inner portion 42 of the fourth lead 4A is split into two portions, on the end portion continuous with the fourth outer portion 41 (ninth portion 41A and tenth portion 41B). Thus, since the ninth portion 41A and the tenth portion 41B are electrically connected to each other via the fourth inner portion 42, the ninth portion 41A and the tenth portion 41B are equipotential.

In the electronic device A2, the ratio of the first distance D1 (see FIG. 14) between the first end 114a of the first cutting mark 114 in the first outer portion 11, on the x2-side of the first direction x, and a first corner portion 149a of the first die pad 14, to the first length L1 (see FIG. 14) of the first outer portion 11 in the second direction y, in a plan view, is defined as follows. Specifically, the first distance D1 is set to be equal to or shorter than 10.8 times as long as the first length L1 (total of length L11 and length L12) (L1/D1≤10.8). For example, the first distance D1 from the first end 114a to the first corner portion 149a is between 5.5 times and 10.8 times as long, both ends inclusive, as the first length L1 of the first outer portion 11 in the second direction y. An example of the specific length of the first length L1 is between 0.2 mm and 0.5 mm, both ends inclusive, and the first distance D1 is between 1.1 mm and 2.2 mm, both ends inclusive.

In the electronic device A2, in addition, the ratio of the second distance D2 (see FIG. 15) between the second end 214a of the second cutting mark 214 in the second outer portion 21, on the x1-side of the first direction x, and a second corner portion 249a of the second die pad 24, to the second length L2 (see FIG. 15) of the second outer portion 21 in the second direction y, in a plan view, is defined as follows. Specifically, the second distance D2 is set to be equal to or shorter than 10.8 times as long as the second length L2 (total of length L21 and length L22) (L2/D2≤10.8). For example, the second distance D2 from the second end 214a to the second corner portion 249a is between 5.5 times and 10.8 times as long, both ends inclusive, as the second length L2 of the second outer portion 21 in the second direction y. An example of the specific length of the second length L2 is between 0.2 mm and 0.5 mm, both ends inclusive, and the second distance D2 is between 1.1 mm and 2.2 mm, both ends inclusive.

In the electronic device A2 also, the deformation of the first lead 1 and the deformation of the second lead 2, in other words the deformation of the lead frame can be suppressed, as in the case of the electronic device A1. In the electronic device A2, the respective lengths L11 and L12 in the second direction y, of the first portion 11A and the second portion 11B constituting the first outer portion 11, is longer than the length of the fourth lead 4B in the second direction y. Therefore, the first length L1 of the first outer portion 11 as a whole in the second direction y can be set to a desired value that satisfies the relational formula L1/D1≤10.8. In addition, the electronic device A2 provides the same advantageous effects as those provided by the electronic device A1, because of the configuration common to the electronic device A1.

### Variation of Second Embodiment

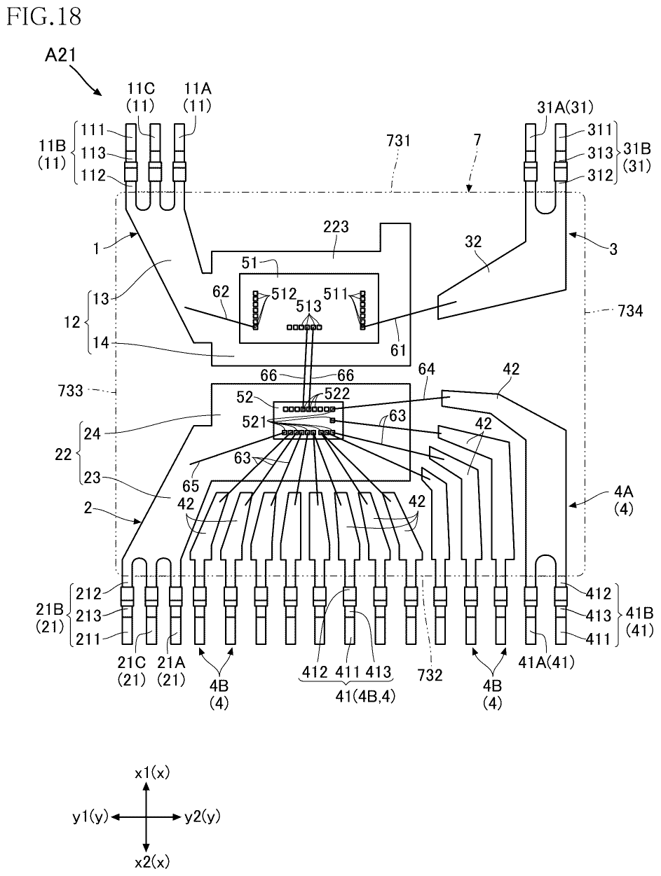

FIG. 18 to FIG. 22 illustrate an electronic device A21 according to a variation of the second embodiment. The electronic device A21 according to this variation is different from the electronic device A2, in the configuration of the first lead 1 and the second lead 2.

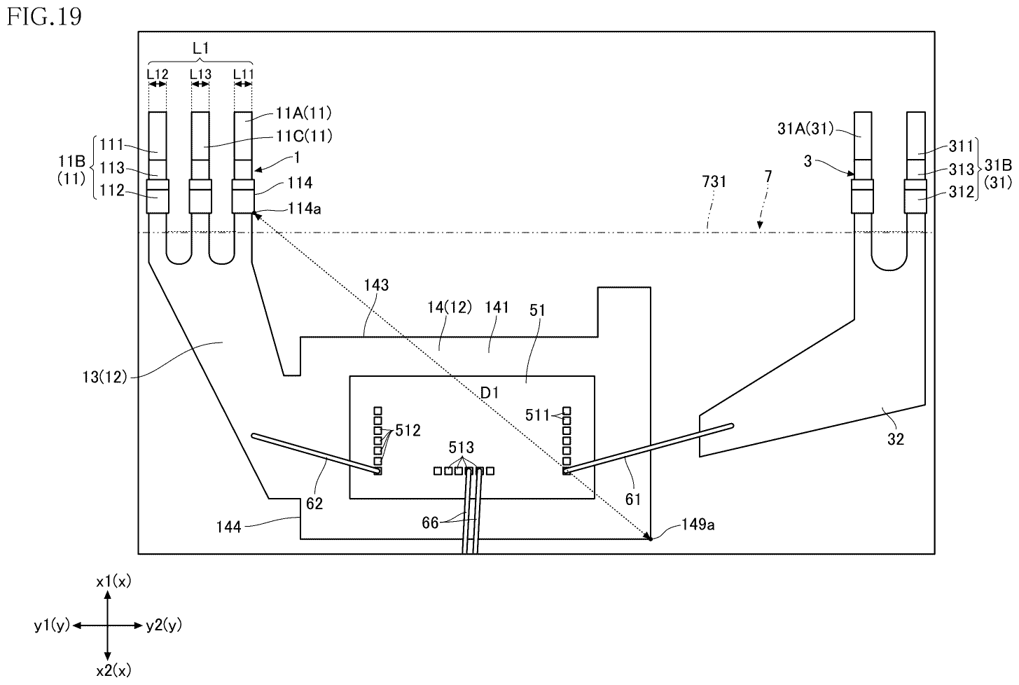

As shown in FIG. 18, FIG. 19, and FIG. 22, the first outer portion 11 of the electronic device A21 includes three portions, namely the first portion 11A, the second portion 11B, and a third portion 11C, spaced apart from each other in the second direction y. Instead of the illustrated example, the number of portions constituting the first outer portion 11 and spaced apart from each other may be four or more. The first portion 11A, the second portion 11B, and the third portion 11C each include the first mounting portion 111, the first basal portion 112, and the first intermediate portion 113.

As shown in FIG. 22, the first portion 11A, the second portion 11B, and the third portion 11C are aligned in the second direction y, with the clearance d11 between each other. Although the clearance d11 is equal to the clearance d44 in the illustrated example, these clearances may be different from each other. Because of such a configuration, the first inner portion 12 of the first lead 1 is split into three portions, on the end portion continuous with the first outer portion 11 (first portion 11A, second portion 11B, and third portion 11C). Thus, since the first portion 11A, the second portion 11B, and the third portion 11C are electrically connected to each other via the first inner portion 12, the first portion 11A, the second portion 11B, and the third portion 11C are equipotential. In the first outer portion 11 configured as above, the first length L1 in the second direction y corresponds to the total of the length L11 of the first portion 11A in the second direction y, the length L12 of the second portion 11B in the second direction y, and the length L13 of the third portion 11C in the second direction y.

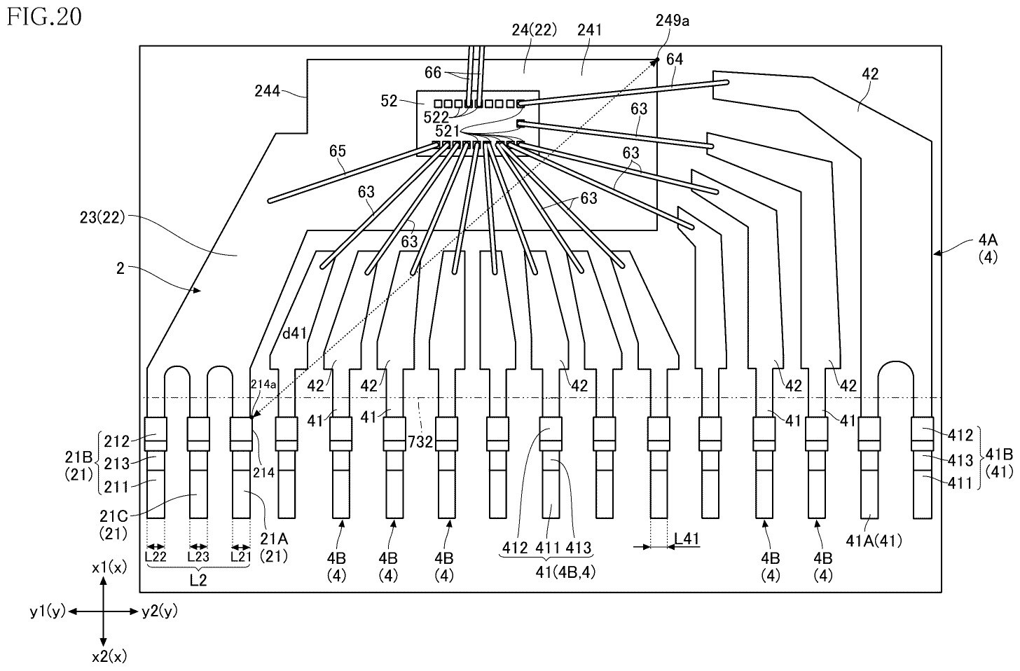

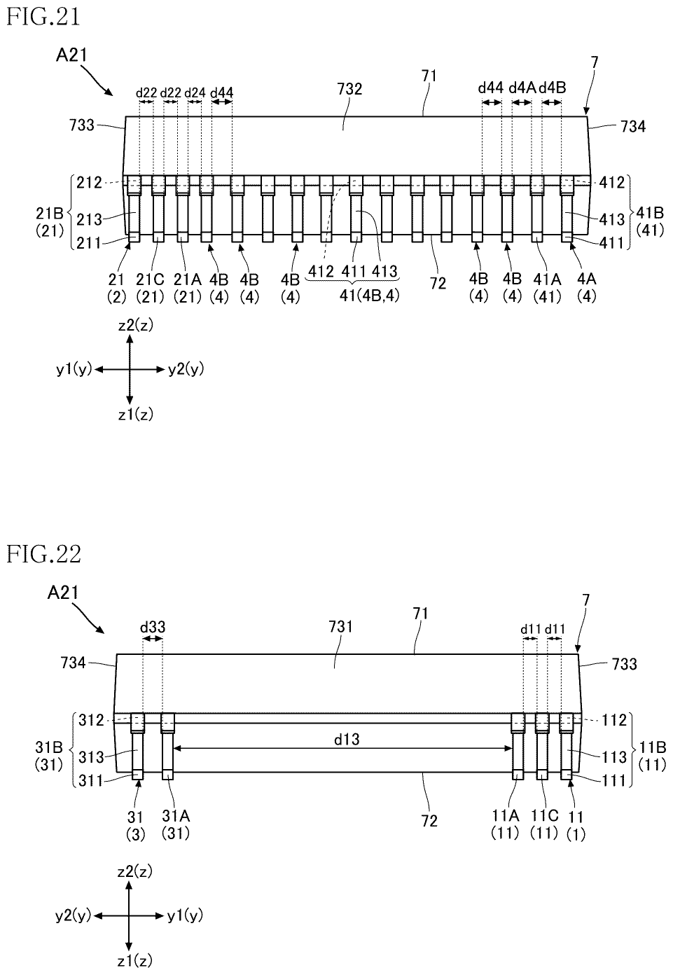

As shown in FIG. 18, FIG. 20, and FIG. 21, the second lead 2 of the electronic device A21 includes three portions, namely the fourth portion 21A, the fifth portion 21B, and a sixth portion 21C, spaced apart from each other in the second direction y. Instead of the illustrated example, the number of portions constituting the second outer portion 21 and spaced apart from each other may be four or more. The fourth portion 21A, the fifth portion 21B, and the sixth portion 21C each include the second mounting portion 211, the second basal portion 212, and the second intermediate portion 213.

As shown in FIG. 21, the fourth portion 21A, the fifth portion 21B, and the sixth portion 21C are aligned in the second direction y, with the clearance d22 between each other. Although the clearance d22 is equal to the clearance d44 in the illustrated example, these clearances may be different from each other. Because of such a configuration, the second inner portion 22 of the second lead 2 is split into three portions, on the end portion continuous with the second outer portion 21 (fourth portion 21A, fifth portion 21B, and sixth portion 21C). Thus, since the fourth portion 21A, the fifth portion 21B, and the sixth portion 21C are electrically connected to each other via the second inner portion 22, the fourth portion 21A, the fifth portion 21B, and the sixth portion 21C are equipotential. In the second outer portion 21 configured as above, the second length L2 in the second direction y corresponds to the total of the length L21 of the fourth portion 21A in the second direction y, the length L22 of the fifth portion 21B in the second direction y, and the length L23 of the sixth portion 21C in the second direction y.

In the electronic device A21, the ratio of the first distance D1 (see FIG. 19) between the first end 114a of the first cutting mark 114 in the first outer portion 11, on the x2-side of the first direction x, and a first corner portion 149a of the first die pad 14, to the first length L1 (see FIG. 19) of the first outer portion 11 in the second direction y, in a plan view, is defined as follows. Specifically, the first distance D1 is set to be equal to or shorter than 10.8 times as long as the first length L1 (total of length L11, length L12, and length L13) (L1/D1≤10.8). For example, the first distance D1 from the first end 114a to the first corner portion 149a is between 5.5 times and 10.8 times as long, both ends inclusive, as the first length L1 of the first outer portion 11 in the second direction y. An example of the specific length of the first length L1 is between 0.2 mm and 0.5 mm, both ends inclusive, and the first distance D1 is between 1.1 mm and 2.2 mm, both ends inclusive.

In the electronic device A21, in addition, the ratio of the second distance D2 (see FIG. 20) between the second end 214a of the second cutting mark 214 in the second outer portion 21, on the x1-side of the first direction x, and a second corner portion 249a of the second die pad 24, to the second length L2 (see FIG. 20) of the second outer portion 21 in the second direction y, in a plan view, is defined as follows. Specifically, the second distance D2 is set to be equal to or shorter than 10.8 times as long as the second length L2 (total of length L21, length L22, and length L23) (L2/D2≤10.8). For example, the second distance D2 from the second end 214a to the second corner portion 249a is between 5.5 times and 10.8 times as long, both ends inclusive, as the second length L2 of the second outer portion 21 in the second direction y. An example of the specific length of the second length L2 is between 0.2 mm and 0.5 mm, both ends inclusive, and the second distance D2 is between 1.1 mm and 2.2 mm, both ends inclusive.

In the electronic device A21 also, the deformation of the first lead 1 and the deformation of the second lead 2, in other words the deformation of the lead frame can be suppressed, as in the case of the electronic device A1. In addition, the electronic device A21 provides the same advantageous effects as those provided by the electronic device A1, because of the configuration common to the electronic device A1.

### Third Embodiment

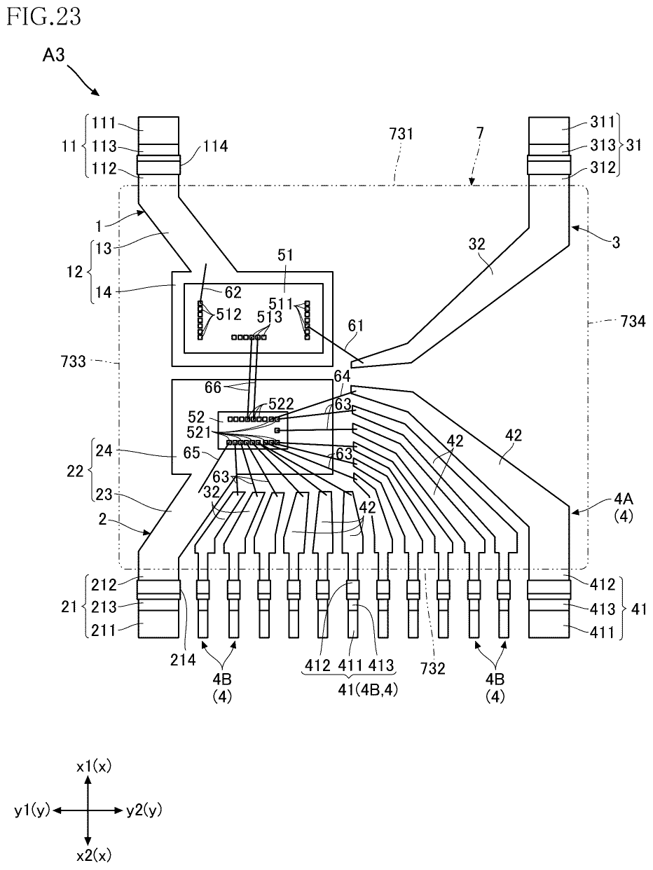

FIG. 23 to FIG. 27 illustrate an electronic device A3 according to a third embodiment of the present disclosure. The electronic device A3 according to this embodiment is different from the electronic device A1, in the configuration of the first lead 1 and the second lead 2.

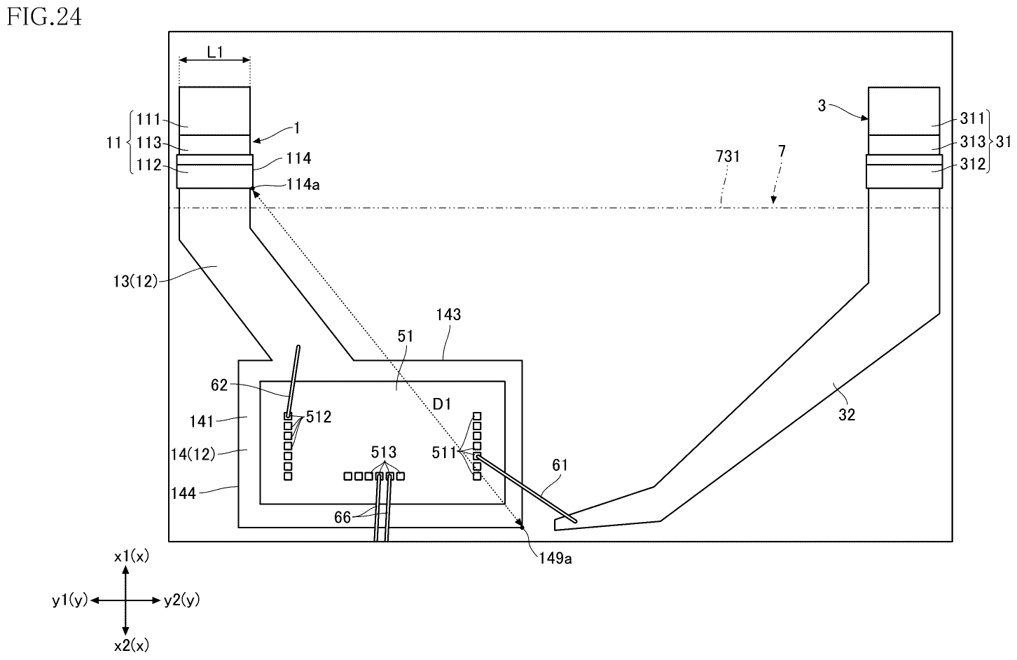

As shown in FIG. 23 and FIG. 24, the first connecting portion 13 of the electronic device A3 is connected to the first side face 143 of the first die pad 14. The first connecting portion 13 is connected to a middle position of the first side face 143, in the second direction y. In the illustrated example, the first connecting portion 13 is connected to a position on the y1-side of the second direction y, of the first side face 143. The first connecting portion 13 is inclined with respect to the first direction x, in a plan view. The inclination angle of the first connecting portion 13 with respect to the first direction x is not specifically limited. However, it is not mandatory that the first connecting portion 13 is inclined with respect to the first direction x, in a plan view.

The center of the first die pad 14 in the second direction y is located on the y2-side of the second direction y, with respect to the center of the first outer portion 11 in the second direction y. In other words, the center of the first outer portion 11 is located on the y1-side of the second direction y, with respect to the center of the first die pad 14 in the second direction y. In this embodiment, as shown in FIG. 23 and FIG. 24, a part of the first basal portion 112 overlaps with the first die pad 14, as viewed in the first direction x. Instead, the entirety of the first basal portion 112 may overlap with the first die pad 14, as viewed in the first direction x. Alternatively, the entirety of the first basal portion 112 may be deviated from the first die pad 14, as viewed in the first direction x. In other words, the first outer portion 11 may be located on the outer side (y1-side of the second direction y) with respect to the first die pad 14, in the second direction y.

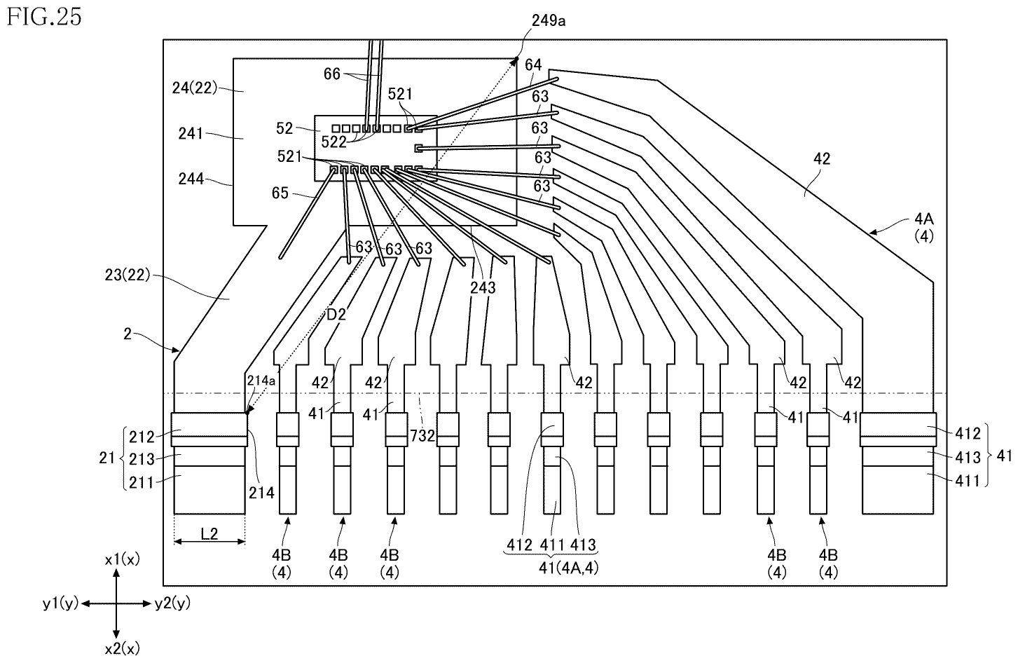

As shown in FIG. 23 and FIG. 25, the second connecting portion 23 of the electronic device A3 is connected to the third side face 243 of the second die pad 24. The second connecting portion 23 is connected to a middle position of the third side face 243, in the second direction y. In the illustrated example, the second connecting portion 23 is connected to a position on the y1-side of the second direction y, of the third side face 243. The second connecting portion 23 is inclined with respect to the first direction x, in a plan view. The inclination angle of the second connecting portion 23 with respect to the first direction x is not specifically limited. However, it is not mandatory that the second connecting portion 23 is inclined with respect to the first direction x, in a plan view.

The center of the second die pad 24 in the second direction y is located on the y2-side of the second direction y, with respect to the center of the second outer portion 21 in the second direction y. In other words, the center of the second outer portion 21 is located on the y1-side of the second direction y, with respect to the center of the second die pad 24 in the second direction y. In this embodiment, as shown in FIG. 23 and FIG. 25, a part of the second basal portion 212 overlaps with the second die pad 24, as viewed in the first direction x. Instead, the entirety of the second basal portion 212 may overlap with the second die pad 24, as viewed in the first direction x. Alternatively, the entirety of the second basal portion 212 may be deviated from the second die pad 24, as viewed in the first direction x. In other words, the second outer portion 21 may be located on the outer side (y1-side of the second direction y) with respect to the second die pad 24, in the second direction y.

In the electronic device A3, the ratio of the first distance D1 (see FIG. 24) between the first end 114a of the first cutting mark 114 in the first outer portion 11, on the x2-side of the first direction x, and a first corner portion 149a of the first die pad 14, to the first length L1 (see FIG. 24) of the first outer portion 11 in the second direction y, in a plan view, is defined as follows. Specifically, the first distance D1 is set to be equal to or shorter than 10.8 times as long as the first length L1 (L1/D1≤10.8). For example, the first distance D1 from the first end 114a to the first corner portion 149a is between 5.5 times and 10.8 times as long, both ends inclusive, as the first length L1 of the first outer portion 11 in the second direction y. An example of the specific length of the first distance D1 is between 1.1 mm and 2.2 mm, both ends inclusive.

In the electronic device A3, in addition, the ratio of the second distance D2 (see FIG. 25) between the second end 214a of the second cutting mark 214 in the second outer portion 21, on the x1-side of the first direction x, and a second corner portion 249a of the second die pad 24, to the second length L2 (see FIG. 25) of the second outer portion 21 in the second direction y, in a plan view, is defined as follows. Specifically, the second distance D2 is set to be equal to or shorter than 10.8 times as long as the second length L2 (L2/D2≤10.8). For example, the second distance D2 from the second end 214a to the second corner portion 249a is between 5.5 times and 10.8 times as long, both ends inclusive, as the second length L2 of the second outer portion 21 in the second direction y. An example of the specific length of the second distance D2 is between 1.1 mm and 2.2 mm, both ends inclusive.

In the electronic device A3 also, the deformation of the first lead 1 and the deformation of the second lead 2, in other words the deformation of the lead frame can be suppressed, as in the case of the electronic device A1. In addition, the electronic device A3 provides the same advantageous effects as those provided by the electronic device A1, because of the configuration common to the electronic device A1.

The electronic device according to the present disclosure is not limited to the foregoing embodiments. The specific configuration of each of the elements of the electronic device according to the present disclosure may be modified in various manners.

Although the center of the first outer portion 11 in the second direction y is located on the y1-side of the second direction y with respect to the center of the first die pad 14 in the second direction y, in the foregoing embodiments and variations thereof, the present disclosure is not limited to such configuration. In the second direction y, the center of the first outer portion 11 may be located at the same position as the center of the first die pad 14. Likewise, without limitation to the configuration where the center of the second outer portion 21 in the second direction y is located on the y1-side of the second direction y with respect to the center of the second die pad 24 in the second direction y, the center of the second outer portion 21 may be located at the same position as the center of the second die pad 24, in the second direction y.

The present disclosure includes the configurations presented as the following clauses.

### Clause 1

An electronic device including:
a first electronic component;
a sealing resin covering the first electronic component; and
a first lead including a first inner portion covered with the sealing resin, and a first outer portion exposed from the sealing resin,
in which the first inner portion includes a first die pad on which the first electronic component is mounted, and a first connecting portion connecting the first outer portion and the first die pad,
the first outer portion is located on one side in a first direction orthogonal to a thickness direction of the first electronic component, with respect to the first die pad,
a center of the first outer portion is, in a second direction orthogonal to the thickness direction and the first direction, located at a same position as a center of the first die pad, or on the one side of the center of the first die pad in the second direction,
the first die pad has a rectangular shape as viewed in the thickness direction, and includes a first corner portion located on the other side in the first direction, and on the other side in the second direction,
the first outer portion includes a first cutting mark oriented to the other side in the second direction, and
a first distance from a first end of the first cutting mark on the other side in the first direction, to the first corner portion is, as viewed in the thickness direction, equal to or shorter than 10.8 times as long as a first length of the first outer portion in the second direction.

### Clause 2

The electronic device according to clause 1,
in which the first die pad includes a first side face oriented to the one side in the first direction, and
the first connecting portion is connected to the first side face.

### Clause 3

The electronic device according to clause 1,
in which the first die pad includes a second side face oriented to the one side in the second direction, and
the second connecting portion is connected to the second side face.

### Clause 4

The electronic device according to any one of clauses 1 to 3,
in which the first outer portion includes a first portion and a second portion, spaced apart from each other in the second direction.

### Clause 5

The electronic device according to clause 4, further including a plurality of terminal leads,
in which the plurality of terminal leads each include a terminal lead inner portion covered with the sealing resin, and a terminal lead outer portion exposed from the sealing resin,
the terminal lead outer portion is spaced apart from the first die pad in the first direction, and
a length of each of the first portion and the second portion in the second direction is longer than a length of the terminal lead outer portion in the second direction, as viewed in the thickness direction.

### Clause 6

The electronic device according to clause 4,
in which the first outer portion includes a third portion spaced apart from the first portion and the second portion, in the second direction.

### Clause 7

The electronic device according to any one of clauses 1 to 6,
in which a first thickness of the first lead in the thickness direction is between 0.2 mm and 0.3 mm, both ends inclusive.

### Clause 8

The electronic device according to any one of clauses 1 to 7,
in which the first distance is between 5.5 times and 10.8 times as long, both ends inclusive, as the first length.

### Clause 9

The electronic device according to any one of clauses 1 to 8,
in which the first connecting portion is inclined with respect to the first direction, as viewed in the thickness direction.

Clause 10

The electronic device according to any one of clauses 1 to 9, further including:
a second electronic component; and
a second lead spaced apart from the first lead,
in which the second lead includes a second inner portion covered with the sealing resin, and a second outer portion exposed from the sealing resin,
the second inner portion includes a second die pad on which the second electronic component is mounted, and a second connecting portion connecting the second outer portion and the second die pad,
the second die pad is located on the other side in the first direction, with respect to the first die pad,
the second outer portion is located on the other side in the first direction, with respect to the second die pad,
a center of the second outer portion is, in the second direction, located at a same position as a center of the second die pad, or on the one side of the center of the second die pad in the second direction,
the second die pad has a rectangular shape as viewed in the thickness direction, and includes a second corner portion located on the one side in the first direction, and on the other side in the second direction,
the second outer portion includes a second cutting mark oriented to the other side in the second direction, and
a second distance from a second end of the second cutting mark on the one side in the first direction, to the second corner portion is, as viewed in the thickness direction, equal to or shorter than 10.8 times as long as a second length of the second outer portion in the second direction.

### Clause 11

The electronic device according to clause 10,
in which the second die pad includes a third side face oriented to the other side in the first direction, and
the second connecting portion is connected to the third side face.

### Clause 12

The electronic device according to clause 10,
in which the second die pad includes a fourth side face oriented to the one side in the second direction, and
the second connecting portion is connected to the fourth side face.

### Clause 13

The electronic device according to any one of clauses 10 to 12,
in which the second outer portion includes a fourth portion and a fifth portion, spaced apart from each other in the second direction.

### Clause 14

The electronic device according to clause 13,
in which the second outer portion includes a sixth portion, spaced apart from the fourth portion and the fifth portion in the second direction.

### Clause 15

The electronic device according to any one of clauses 10 to 14,
in which a second thickness of the second lead in the thickness direction is between 0.2 mm and 0.3 mm, both ends inclusive.

### Clause 16

The electronic device according to any one of clauses 10 to 15,
in which the second distance is between 5.5 times and 10.8 times as long, both ends inclusive, as the second length.

### Clause 17

The electronic device according to any one of clauses 10 to 16,
in which the second connecting portion is inclined with respect to the first direction, as viewed in the thickness direction.

1. An electronic device comprising:
a first electronic component;
a sealing resin covering the first electronic component; and
a first lead including a first inner portion covered with the sealing resin, and a first outer portion exposed from the sealing resin,
wherein the first inner portion includes a first die pad on which the first electronic component is mounted, and a first connecting portion connecting the first outer portion and the first die pad,
the first outer portion is located on one side in a first direction with respect to the first die pad, the first direction being orthogonal to a thickness direction of the first electronic component,
a center of the first outer portion is, in a second direction orthogonal to the thickness direction and the first direction, located at a same position as a center of the first die pad, or on one side of the center of the first die pad in the second direction,
the first die pad has a rectangular shape as viewed in the thickness direction, and includes a first corner portion located on an other side in the first direction, and on an other side in the second direction,
the first outer portion includes a first cutting mark oriented to the other side in the second direction, and
a first distance from a first end of the first cutting mark on the other side in the first direction, to the first corner portion is, as viewed in the thickness direction, equal to or shorter than 10.8 times as long as a first length of the first outer portion in the second direction.

2. The electronic device according to claim 1, wherein the first die pad includes a first side face oriented to the one side in the first direction, and
the first connecting portion is connected to the first side face.

3. The electronic device according to claim 1, wherein the first die pad includes a second side face oriented to the one side in the second direction, and
the second connecting portion is connected to the second side face.

4. The electronic device according to claim 1, wherein the first outer portion includes a first portion and a second portion that are spaced apart from each other in the second direction.

5. The electronic device according to claim 4, further comprising a plurality of terminal leads,
wherein the plurality of terminal leads each include a terminal lead inner portion covered with the sealing resin, and a terminal lead outer portion exposed from the sealing resin,
the terminal lead outer portion is spaced apart from the first die pad in the first direction, and
a length of each of the first portion and the second portion in the second direction is longer than a length of the terminal lead outer portion in the second direction, as viewed in the thickness direction.

6. The electronic device according to claim 4, wherein the first outer portion includes a third portion spaced apart from the first portion and the second portion, in the second direction.

7. The electronic device according to claim 1, wherein a first thickness of the first lead in the thickness direction is between 0.2 mm and 0.3 mm, both ends inclusive.

8. The electronic device according to claim 1, wherein the first distance is between 5.5 times and 10.8 times as long as the first length, both ends inclusive.

9. The electronic device according to claim 1, wherein the first connecting portion is inclined with respect to the first direction, as viewed in the thickness direction.

10. The electronic device according to claim 1, further comprising:
a second electronic component; and
a second lead spaced apart from the first lead,
wherein the second lead includes a second inner portion covered with the sealing resin, and a second outer portion exposed from the sealing resin,
the second inner portion includes a second die pad on which the second electronic component is mounted, and a second connecting portion connecting the second outer portion and the second die pad,
the second die pad is located on the other side in the first direction, with respect to the first die pad,
the second outer portion is located on the other side in the first direction, with respect to the second die pad,
a center of the second outer portion is, in the second direction, located at a same position as a center of the second die pad, or on one side of the center of the second die pad in the second direction,
the second die pad has a rectangular shape as viewed in the thickness direction, and includes a second corner portion located on the one side in the first direction, and on the other side in the second direction,
the second outer portion includes a second cutting mark oriented to the other side in the second direction, and
a second distance from a second end of the second cutting mark on the one side in the first direction, to the second corner portion is, as viewed in the thickness direction, equal to or shorter than 10.8 times as long as a second length of the second outer portion in the second direction.

11. The electronic device according to claim 10, wherein the second die pad includes a third side face oriented to the other side in the first direction, and the second connecting portion is connected to the third side face.

12. The electronic device according to claim 10, wherein the second die pad includes a fourth side face oriented to the one side in the second direction, and
the second connecting portion is connected to the fourth side face.

13. The electronic device according to claim 10, wherein the second outer portion includes a fourth portion and a fifth portion that are spaced apart from each other in the second direction.

14. The electronic device according to claim 13, wherein the second outer portion includes a sixth portion spaced apart from the fourth portion and the fifth portion in the second direction.

15. The electronic device according to claim 10, wherein a second thickness of the second lead in the thickness direction is between 0.2 mm and 0.3 mm, both ends inclusive.

16. The electronic device according to claim 10, wherein the second distance is between 5.5 times and 10.8 times as long as the second length, both ends inclusive.

17. The electronic device according to claim 10, wherein the second connecting portion is inclined with respect to the first direction, as viewed in the thickness direction.
